(19) United States
(12) Patent Application Publication
(10) Pub. No.: US 2026/0144002 A1
(43) Pub. Date: May 21, 2026

(54) TRANSFER SYSTEM

(71) Applicant: KABUSHIKI KAISHA YASKAWA DENKI, Fukuoka (JP)

(72) Inventors: Mina ORII, Fukuoka (JP); Yoshiaki KUBOTA, Fukuoka (JP); Akira TAJIMA, Fukuoka (JP); Akihito TOYOTA, Fukuoka (JP); Hiromitsu AKAE, Fukuoka (JP); Fumihiro TARA, Fukuoka (JP); Miyabi TERASHIMA, Fukuoka (JP); Yuki HONDA, Fukuoka (JP); Yukiko NAKAYAMA, Fukuoka (JP)

(21) Appl. No.: 19/388,096

(22) Filed: Nov. 13, 2025

(30) Foreign Application Priority Data
Nov. 15, 2024 (JP) 2024-200089

(51) Int. Cl. H01L 21/677; H01L 21/67

(52) U.S. Cl. CPC H10P 72/3208; H10P 72/0454; H10P 72/3204

(57) ABSTRACT

A substrate transfer system includes: a transfer chamber equipped with a transfer path along which a workpiece is transferred; a plurality of processing chambers that is arranged along a first direction around the transfer chamber, and performs a predetermined process on the workpiece; a plurality of stators each including a coil and arranged along the transfer path in the transfer chamber; and a mover that includes a magnet, and levitates and moves on the transfer path to transfer the workpiece. The transfer path includes a first transfer path in which the plurality of stators are arranged in a row along the first direction.

### CROSS REFERENCES TO RELATED APPLICATIONS

This application is based on and claims priority from Japanese Patent Application No. 2024-200089, filed on Nov. 15, 2024, with the Japan Patent Office, the disclosure of which is incorporated herein in its entirety by reference.

### TECHNICAL FIELD

The present disclosure relates to a transfer system.

### BACKGROUND

Japanese National Publication of International Patent Application No. 2018-504784 discloses semiconductor processing equipment that is used to transfer semiconductor substrates between processing chambers. The semiconductor processing equipment includes a planar motor having an array of coils, and a substrate carrier including a magnet to levitate by interaction between a magnetic field generated by the coils and a magnetic field generated by the magnet, so that its position is controlled. The substrate carrier has a substrate support surface for placing a substrate thereon, and transfers the substrate between the processing chambers.

### SUMMARY

In the conventional semiconductor processing equipment described above, the trajectory or control of the substrate carrier is complicated, which results in an increase in size of the equipment and lack of expandability.

The present disclosure has been made in consideration of the problems above, and provides a transfer system, which may downsize equipment and improve expandability.

According to an aspect of the present disclosure, a transfer system includes: a transfer chamber including a transfer path along which a workpiece is transferred; a plurality of processing chambers that is arranged along a first direction around the transfer chamber, and performs a predetermined process on the workpiece; a plurality of stators each including a coil and arranged along the transfer path in the transfer chamber; and a mover that includes a magnet, and levitates and moves on the transfer path to transfer the workpiece, wherein the transfer path includes a first transfer path in which the plurality of stators are arranged in a row along the first direction.

According to the present disclosure, the equipment may be downsized, and the expandability may be improved.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view conceptually illustrating an example of an overall configuration of a substrate transfer system.

FIG. 2 is a view conceptually illustrating an example of a stator unit and a coil configuration of a stator.

FIG. 3 is a view conceptually illustrating an example of a configuration of a mover.

FIG. 4 is a view illustrating an example of an operation control when two movers pass each other.

FIG. 5 is a view illustrating an example of an operation control when one mover overtakes another mover.

FIG. 6 is a view illustrating an example of an operation control when a moving mover bypasses another mover.

FIG. 7 is a view illustrating an example of an operation control when a mover is controlled to approach a specific processing chamber from one side in an X-axis direction.

FIG. 8 is a view illustrating an example of an operation when a mover is controlled to detour and approach a specific processing chamber from the other side in the X-axis direction.

FIG. 9 is a view illustrating an example of an operation control to prevent collision between movers.

FIG. 10 is a view illustrating another example of the operation control to prevent the collision between movers.

FIG. 11 is a plan view illustrating an example of the configuration of the stator unit when viewed from above.

FIG. 12 is a cross-sectional view illustrating an example of the cross-sectional structure of the stator unit, which corresponds to XII-XII cross section in FIG. 11.

FIG. 13 is a view illustrating an example of an arrangement of sensor substrates and sensors in the stator unit.

FIG. 14 is a view illustrating another example of the arrangement of the sensor substrates and the sensors in the stator unit.

FIG. 15 is a view illustrating an example of a direction of heat transfer by a heat transfer member.

FIG. 16 is a perspective view illustrating an example of a layer configuration of a coil unit.

FIG. 17 is a perspective view illustrating an example of a layer configuration of a first substrate coil unit.

FIG. 18 is a perspective view illustrating an example of a layer configuration of a second substrate coil unit.

FIG. 19 is a conceptual view illustrating an example of the layer configuration of the first substrate coil unit.

FIG. 20 is a conceptual view illustrating an example of the layer configuration of the second substrate coil unit.

FIG. 21 is a top view illustrating an example of the shape of first coil patterns in the first substrate coil unit.

FIG. 22 is a top view illustrating an example of the shape of the first coil patterns in the first substrate coil unit.

FIG. 23 is a top view illustrating an example of the shape of the first coil patterns in the first substrate coil unit.

FIG. 24 is a top view illustrating an example of the shape of second coil patterns in the second substrate coil unit.

FIG. 25 is a top view illustrating an example of the shape of the second coil patterns in the second substrate coil unit.

FIG. 26 is a top view illustrating an example of the shape of the second coil patterns in the second substrate coil unit.

FIG. 27 is a circuit diagram illustrating an example of a servo amplifier that supplies current to a first substrate coil, and a circuit configuration.

FIG. 28 is a circuit diagram illustrating an example of a servo amplifier that supplies current to a first substrate coil, and a circuit configuration.

FIG. 29 is a circuit diagram illustrating an example of a servo amplifier that supplies current to a second substrate coil, and a circuit configuration.

FIG. 30 is a circuit diagram illustrating an example of a servo amplifier that supplies current to a second substrate coil, and a circuit configuration.

FIG. 31 is a view illustrating an example of a region where a propulsion force in an X-axis direction is obtained, in a coil unit of a stator.

FIG. 32 is a view illustrating an example of a region where a propulsion force in a Y-axis direction is obtained, in a coil unit of a stator.

FIG. 33 is a view illustrating an example of a region where a levitation force in a Z-axis direction is reliably obtained, in a coil unit of a stator.

FIG. 34 is a view illustrating an example of a relationship between a size of a coil unit of a stator and a magnet unit of a mover.

FIG. 35 is a view conceptually illustrating an example of an overall configuration of a substrate transfer system according to a modification in which a second transfer path is formed at a position facing a processing chamber.

FIG. 36 is a view illustrating variation of arrangement of stators in the stator unit.

FIG. 37 is a view illustrating variation of arrangement of stators in the stator unit.

FIG. 38 is a view illustrating variation of arrangement of stators in the stator unit.

FIG. 39 is a view illustrating variation of arrangement of stators in the stator unit.

FIG. 40 is a view illustrating variation of arrangement of stators in the stator unit.

FIG. 41 is a view illustrating variation of arrangement of stators in the stator unit.

FIG. 42 is a view illustrating an example of connection of stator units according to a modification.

FIG. 43 is a view illustrating an example of connection of stator units according to a modification.

FIG. 44 is a view illustrating an example of the shape of first coil patterns, in a modification in which first coil patterns and second coil patterns are formed on both sides of a common substrate.

FIG. 45 is a view illustrating an example of the shape of second coil patterns, in a modification in which first coil patterns and second coil patterns are formed on both sides of a common substrate.

FIG. 46 is a conceptual view illustrating variation of a coil configuration of the coil unit.

FIG. 47 is a conceptual view illustrating variation of the coil configuration of the coil unit.

FIG. 48 is a conceptual view illustrating variation of the coil configuration of the coil unit.

FIG. 49 is a conceptual view illustrating variation of the coil configuration of the coil unit.

FIG. 50 is a conceptual view illustrating variation of the coil configuration of the coil unit.

FIG. 51 is a conceptual view illustrating variation of the coil configuration of the coil unit.

FIG. 52 is a view conceptually illustrating an example of an overall configuration of a substrate transfer system, which distinguishably represents a first stator and a second stator, in a modification in which a winding configuration of substrate coils differs between the first stator and the second stator.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment of the present disclosure will be described with reference to the drawings.

### 1. Configuration of Substrate Transfer System

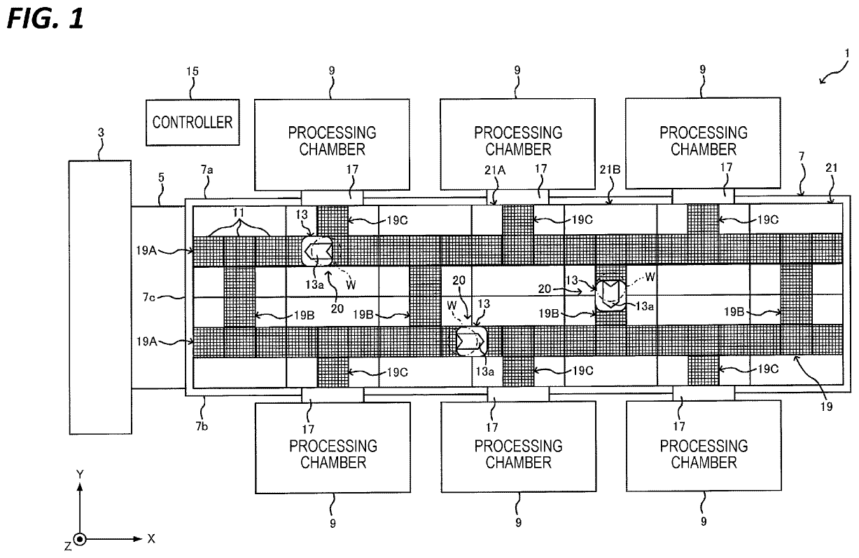

An example of the configuration of a substrate transfer system according to an embodiment of the present disclosure will be described with reference to FIGS. 1 to 3. A substrate transfer system 1 transfers a semiconductor substrate W (an example of a workpiece) under a vacuum environment, and performs predetermined processes on the semiconductor substrate W. The semiconductor substrate W may also be referred to as a semiconductor wafer. The substrate transfer system 1 may transfer workpieces other than the semiconductor substrate W and perform predetermined processes thereon.

FIG. 1 conceptually illustrates an example of the overall configuration of the substrate transfer system 1. As illustrated in FIG. 1, the substrate transfer system 1 (as an example of a transfer system) includes an atmospheric transfer chamber 3, a load lock chamber 5, a vacuum transfer chamber 7, a plurality of processing chambers 9, stators 11, movers 13, and a controller 15.

The atmospheric transfer chamber 3 is maintained in an atmospheric environment, and is provided with an atmospheric transfer device (not illustrated) that transfers the semiconductor substrate W. The atmospheric transfer device takes out the semiconductor substrate W accommodated in a load port (not illustrated), and loads the taken-out semiconductor substrate W in the load lock chamber 5. Further, the atmospheric transfer device takes out the semiconductor substrate W loaded in the load lock chamber 5, and accommodates the taken-out semiconductor substrate W in the load port.

The load lock chamber 5 includes a loading stage (not illustrated) for loading the semiconductor substrate W thereon, and controls the pressure between the atmospheric pressure and vacuum when the semiconductor substrate W is transferred between the atmospheric transfer chamber 3 and the vacuum transfer chamber 7.

The inside of the vacuum transfer chamber 7 (an example of a transfer chamber) is depressurized to vacuum atmosphere, and the semiconductor substrate W is transferred under the vacuum atmosphere. In the example illustrated in FIG. 1, the vacuum transfer chamber 7 is formed, for example, in a substantially rectangular shape when viewed from above. A plurality of processing chambers 9 (e.g., each three of total six processing chambers 9) is connected to each of walls 7a and 7b facing each other on the long sides of the vacuum transfer chamber 7 via opening/closing doors 17. The load lock chamber 5 is connected to a wall 7c on one of the short sides of the vacuum transfer chamber 7 via an opening/closing door (not illustrated). In the present embodiment, the longitudinal direction of the vacuum transfer chamber 7, i.e., the direction in which the plurality of processing chambers 9 provided with the opening/closing doors 17 in the same direction are arranged side by side along the wall 7a or 7b of the vacuum transfer chamber 7, will be referred to as an X-axis direction (e.g., a first direction). The width direction of the vacuum transfer chamber 7, for example, the direction in which the two processing chambers 9 provided with the opening/closing doors 17 in opposite directions face each other, will be referred to as a Y-axis direction (e.g., a second direction). The vertical direction will be referred to as a Z-axis direction. The X-axis direction, the Y-axis direction, and the Z-axis direction are perpendicular to one another. The X-axis direction and the Y-axis direction may not necessarily be perpendicular to each other, and may intersect each other. In this case, the vacuum transfer chamber 7 may have a shape other than the rectangular shape (e.g., parallelogram or trapezoid).

In the vacuum transfer chamber 7, a transfer path 19 is provided, along which the semiconductor substrate W is transferred. The transfer path 19 is formed by arranging a plurality of stators 11 in a row. The transfer path 19 includes a first transfer path 19A, a second transfer path 19B, and a third transfer path 19C. The first transfer path 19A is formed by arranging the plurality of stators 11 in a row along the X-axis direction. In the vacuum transfer chamber 7, two first transfer paths 19A are arranged to be spaced apart from each other in the Y-axis direction and extend substantially parallel to each other in the X-axis direction. The number of first transfer paths 19A is not limited to two, and may be one, or three or more.

The second transfer path 19B is formed by arranging at least one stator 11 in a row along the Y-axis direction, and connects the two first transfer paths 19A in the Y-axis direction. In the example illustrated in FIG. 1, for example, four second transfer paths 19B are arranged. Among the four second transfer paths 19B, the two inner second transfer paths 19B connect the two first transfer paths 19A at positions between two adjacent processing chambers 9 in the X-axis direction. Each second transfer path 19B is formed by, for example, two stators 11. The second transfer path 19B may be formed by a single stator 11 or three or more stators 11.

The third transfer path 19C is formed by arranging at least one stator 11 in a row along the Y-axis direction, and connects the first transfer path 19A and a processing chamber 9. In the example illustrated in FIG. 1, for example, six third transfer paths 19C are arranged to connect the first transfer path 19A to the six processing chambers 9, respectively. Each third transfer path 19C is formed by, for example, a single stator 11. The third transfer path 19C may be formed by two or more stators 11.

The stators 11 each include a plurality of coils, and are arranged along the transfer path 19 in the vacuum transfer chamber 7. Each stator 11 is formed in a substantially quadrilateral shape (e.g., rectangular or square) when viewed from the Z-axis direction. Each mover 13 includes a plurality of magnets, and levitates and moves on the transfer path 19 to transfer the semiconductor substrate W. The stator 11 and the mover 13 make up a planar motor 20. The mover 13 levitates by interaction between a magnetic field generated by the coils of the stator 11 and a magnetic field of the magnets of the mover 13, so that its position is controlled by the controller 15. The mover 13 includes a substrate support unit 13a that supports the semiconductor substrate W. The mover 13 transfers the semiconductor substrate W between the load lock chamber 5 and the processing chambers 9, and among the plurality of processing chambers 9. While FIG. 1 illustrates, for example, three movers 13, the number of movers 13 may be one, or two or more other than three. The number of movers 13 may be at least two.

The processing chambers 9 are arranged around the vacuum transfer chamber 7, and predetermined processes are performed on the semiconductor substrate W therein. In the example illustrated in FIG. 1, for example, the six processing chambers 9 are connected to the walls 7a and 7b, with three processing chambers connected to each wall, via the opening/closing doors 17. The three processing chambers 9 connected to the wall 7a are arranged along the X-axis direction, and the three processing chambers 9 connected to the wall 7b are arranged along the X-axis direction. In each processing chamber 9, a predetermined process, such as film formation, etching, ashing, or cleaning, is performed on the semiconductor substrate W. The number of processing chambers 9 is not particularly limited, and may be one, or two or more other than six according to the number of processes to be performed. Each opening/closing door 17 opens and closes an opening of a processing chamber 9. The opening/closing door 17 may be called a gate valve. In each processing chamber 9, the semiconductor substrate W is transferred to/from the substrate support unit 13a of the mover 13 in the state where the opening/closing door 17 is opened.

The controller 15 controls an operation of each component of the substrate transfer system 1. For example, the controller 15 controls, for example, a process on the semiconductor substrate W in each processing chamber 9, a position of each mover 13 and the operation of the substrate support unit 13a in the vacuum transfer chamber 7, and the opening and closing of the opening/closing door 17. The controller 15 is configured with, for example, a computer. Although not illustrated, the controller 15 may include, for example, a processor such as a CPU, a memory such as ROM or RAM, an input device, an output device, a record device, and a communication device.

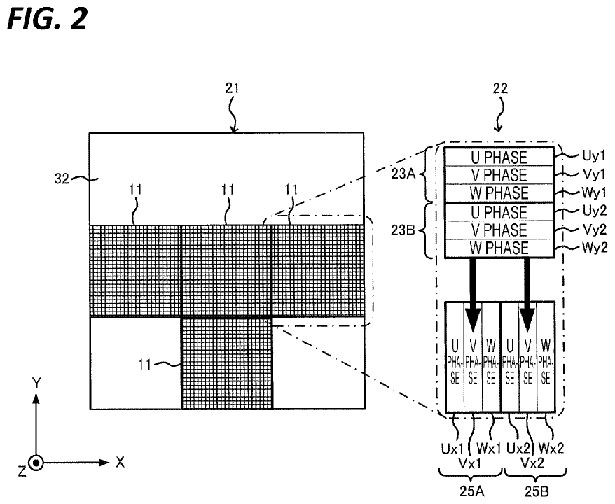

FIG. 2 conceptually illustrates an example of the stator unit 21 and the coil configuration of the stator 11. As illustrated in FIG. 2, the stator unit 21 is configured as a unit including a base 32 having a larger area than the stators 11 when viewed from the Z-axis direction, and the plurality of stators 11 (e.g., four in the example illustrated in FIG. 2) arranged on the upper surface of the base 32. The transfer path 19 is formed by connecting a plurality of stator units 21. Details of the configuration of the stator unit 21 will be described herein later.

Each stator 11 includes a coil unit 22. The coil unit 22 is configured as a coil unit in which a plurality of substrate coils is integrated. The coil unit 22 includes two sets of first substrate coils 23A and 23B each formed in a substantially rectangular shape with its longitudinal direction following the X-axis direction and each including a plurality of substrate coils having different phases (e.g., three U, V, and W phases in the example illustrated in FIG. 2), and two sets of second substrate coils 25A and 25B each formed in a substantially rectangular shape with its longitudinal direction following the Y-axis direction and each including a plurality of substrate coils having different phases (e.g., three U, V, and W phases in the example illustrated in FIG. 2). The first substrate coil 23A includes a U-phase substrate coil Uy1, a V-phase substrate coil Vy1, and a W-phase substrate coil Wy1. The substrate coils Uy1, Vy1, and Wy1 are each formed in a substantially rectangular shape with its longitudinal direction following the X-axis direction, and are arranged adjacent to each other in the Y-axis direction. Similarly, the first substrate coil 23B includes a U-phase substrate coil Uy2, a V-phase substrate coil Vy2, and a W-phase substrate coil Wy2. The substrate coils Uy2, Vy2, and Wy2 are each formed in a substantially rectangular shape with its longitudinal direction following the X-axis direction, and are arranged adjacent to each other in the Y-axis direction. The two first substrate coils 23A and 23B are arranged adjacent to each other in the Y-axis direction.

The second substrate coil 25A includes a U-phase substrate coil Ux1, a V-phase substrate coil Vx1, and a W-phase substrate coil Wx1. The substrate coils Ux1, Vx1, and Wx1 are each formed in a substantially rectangular shape with its longitudinal direction following the Y-axis direction, and are arranged adjacent to each other in the X-axis direction. Similarly, the second substrate coil 25B includes a U-phase substrate coil Ux2, a V-phase substrate coil Vx2, and a W-phase substrate coil Wx2. The substrate coils Ux2, Vx2, and Wx2 are each formed in a substantially rectangular shape with its longitudinal direction following the Y-axis direction, and are arranged adjacent to each other in the X-axis direction. The two second substrate coils 25A and 25B are arranged adjacent to each other in the X-axis direction.

The coil unit 22 is configured by stacking the two first substrate coils 23A and 23B and the two second substrate coils 25A and 25B in the Z-axis direction. Details of the configuration of the coil unit 22 will be described herein later. FIG. 2 illustrates an example where the second substrate coils 25A and 25B are stacked under the first substrate coils 23A and 23B. However, in reverse, the first substrate coils 23A and 23B may be stacked under the second substrate coils 25A and 25B. Further, the number of sets of the first substrate coils 23A and 23B or the second substrate coils 25A and 25B is not limited to two, when one set includes the three U, V, and W phases. For example, a single set may be provided, or three or more sets may be provided. Further, the number of first substrate coils 23A and 23B and the number of second substrate coils 25A and 25B may not necessarily be the same, and may be different from each other.

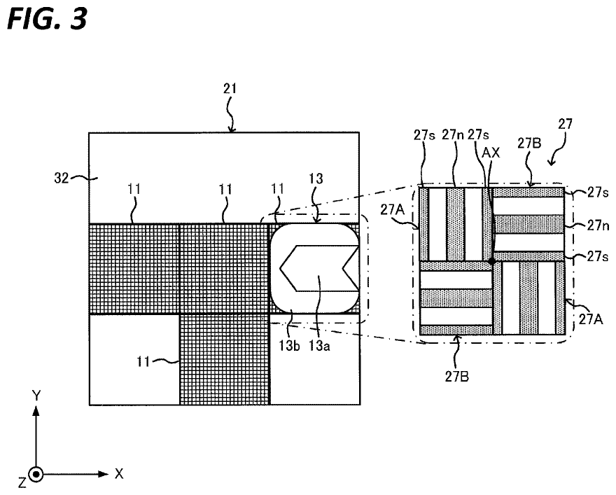

FIG. 3 conceptually illustrates an example of the configuration of the mover 13. As illustrated in FIG. 3, the mover 13 includes the substrate support unit 13a described above, and a base 13b. The mover 13 is formed in a substantially quadrilateral shape (e.g., rectangular or square) when viewed from the Z-axis direction. Further, when viewed from the Z-axis direction, the dimensions of the mover 13 in both the X-axis direction and the Y-axis direction are substantially the same as those of the stator 11. Further, the mover 13 may not have the same size as the stator 11, as long as its size prevents two movers from passing each other on the transfer path 19. Further, the mover 13 may be configured such that its dimension in either the X-axis direction or the Y-axis direction is substantially the same as that of the stator 11.

The mover 13 includes a magnet unit 27 in the base 13b, and levitates and moves on the stator 11. The magnet unit 27 includes four magnet units 27A and 27B configured with two magnet units 27A and two magnet units 27B. The magnet units 27A and the magnet units 27B are different in orientation. Each magnet unit 27A includes a permanent magnet 27n elongated in the Y-axis direction with its N-pole side facing the stator 11 and a permanent magnet 27s elongated in the Y-direction with its S-pole side facing the stator 11, and has a Halbach array in which a separate permanent magnet is inserted between the permanent magnets 27n and 27s such that its magnetization direction is orthogonal to the magnetization directions of the permanent magnets 27n and 27s. Each magnet unit 27B includes a permanent magnet 27n elongated in the X-axis direction with its N-pole side facing the stator 11 and a permanent magnet 27s elongated in the X-direction with its S-pole side facing the stator 11, and has a Halbach array in which a separate permanent magnet is inserted between the permanent magnets 27n and 27s such that its magnetization direction is orthogonal to the magnetization directions of the permanent magnets 27n and 27s. The four magnet units 27A and 27B are alternately arranged around a rotation axis AX. That is, the two magnet units 27A are arranged to be point-symmetrical about the rotation axis AX, and the two magnet units 27B are arranged to be point-symmetrical about the rotation axis AX. When viewed from the Z-axis direction, the region where the magnet unit 27 is disposed has substantially the same dimensions in both the X-axis direction and the Y-axis direction as those of the stator 11.

The mover 13 obtains a propulsion force in the X-axis direction through interaction between a magnetic field by the second substrate coils 25A and 25B of the stator 11 and a magnetic field by the magnet units 27A. Further, the mover 13 obtains a propulsion force in the Y-axis direction through interaction between a magnetic field by the first substrate coils 23A and 23B of the stator 11 and a magnetic field by the magnet units 27B. Further, the mover 13 obtains a propulsion force in a rotation direction around the rotation axis AX through combination of the propulsion force in the X-axis direction and the propulsion force in the Y-axis direction. As a result, the mover 13 may move in a horizontal direction (e.g., each direction on an XY plane, including the X-axis direction and the Y-axis direction), and rotate in the rotation direction around the rotation axis AX. That is, the mover 13 may move with three degrees of freedom. Further, the mover 13 obtains a levitation force in the Z-axis direction through interaction between the magnetic field by the first substrate coils 23A and 23B and the second substrate coils 25A and 25B and the magnetic field by the magnet units 27A and 27B. Thus, by adjusting the current phases of the first substrate coils 23A and 23B and the second substrate coils 25A and 25B, it is possible to adjust the levitation height in the Z-axis direction, the inclination of θx that is a rotation direction around the X axis, and the inclination of θy that is a rotation direction around the Y axis. In this case, movements with six degrees of freedom are possible.

### 2. Operation Control for Mover

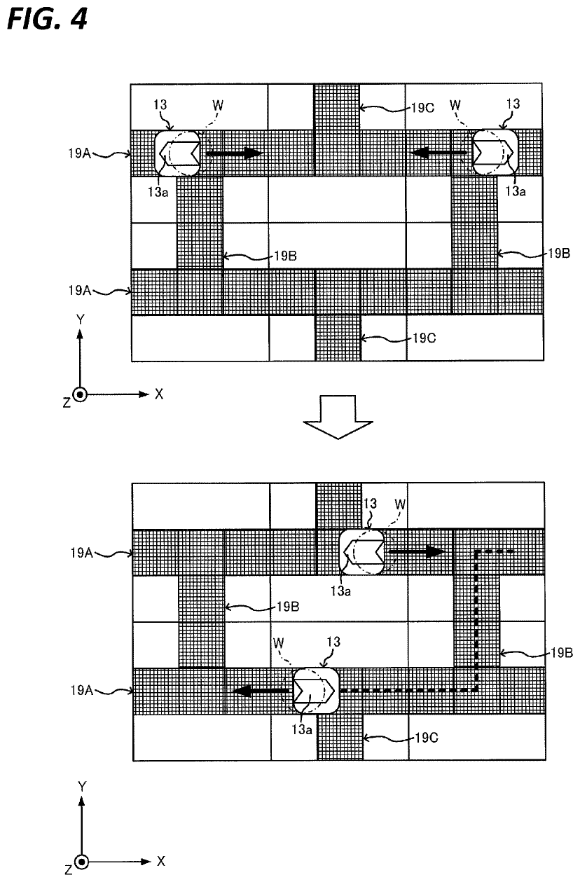

The controller 15 independently controls currents supplied to the substrate coils 23A, 23B, 25A, and 25B of the stator 11, for each stator 11. Further, the controller 15 independently controls the currents supplied to the four substrate coils 23A, 23B, 25A, and 25B of the stator 11, for each substrate coil. Thus, the controller 15 may independently control the operations of the plurality of movers 13, for each mover 13. Next, a specific example of the operation control for the mover 13 by the controller 15 will be described with reference to FIGS. 4 to 10. In FIGS. 4 to 10, for the convenience of description, the positive side of the Y-axis direction will be referred to as an upper side, the negative side of the Y-axis direction will be referred to as a lower side, the positive side of the X-axis direction will be referred to as a right side, and the negative side of the X-axis direction will be referred to as a left side.

FIG. 4 illustrates an example of the operation control when two movers 13 pass each other. When two movers 13 move in the direction approaching each other on the upper-side first transfer path 19A (an example of one first transfer path) as illustrated in the upper view of FIG. 4, the controller 15 controls the mover 13 located on the right side (e.g., an example of one mover) to move to the lower-side first transfer path 19A (e.g., an example of the other first transfer path) via the second transfer path 19B so that the two movers 13 pass each other as illustrated in the lower view of FIG. 4. In this case, the controller 15 may return the mover 13 that has been moved to the lower-side first transfer path 19A, back to the upper-side first transfer path 19A via the second transfer path 19B, or control the mover 13 to continue to move on the lower-side first transfer path 19A.

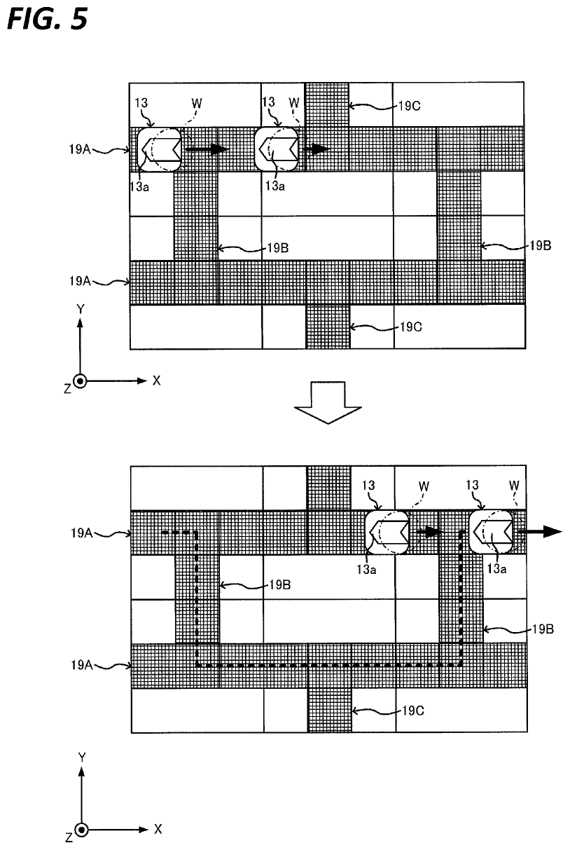

FIG. 5 illustrates an example of the operation control when one mover 13 overtakes another mover 13. When two movers 13 move in the same direction on the upper-side first transfer path 19A (e.g., an example of one first transfer path) as illustrated in the upper view of FIG. 5, the controller 15 controls the mover 13 on the rear side in the moving direction to move to the lower-side first transfer path 19A (e.g., an example of the other first transfer path) via the second transfer path 19B, thereby overtaking the mover 13 on the front side in the moving direction, as illustrated in the lower view of FIG. 5. In this case, the controller 15 may perform at least one of reducing the speed of the mover 13 on the front side in the moving direction (including stopping) and increasing the speed of the mover 13 on the rear side in the moving direction.

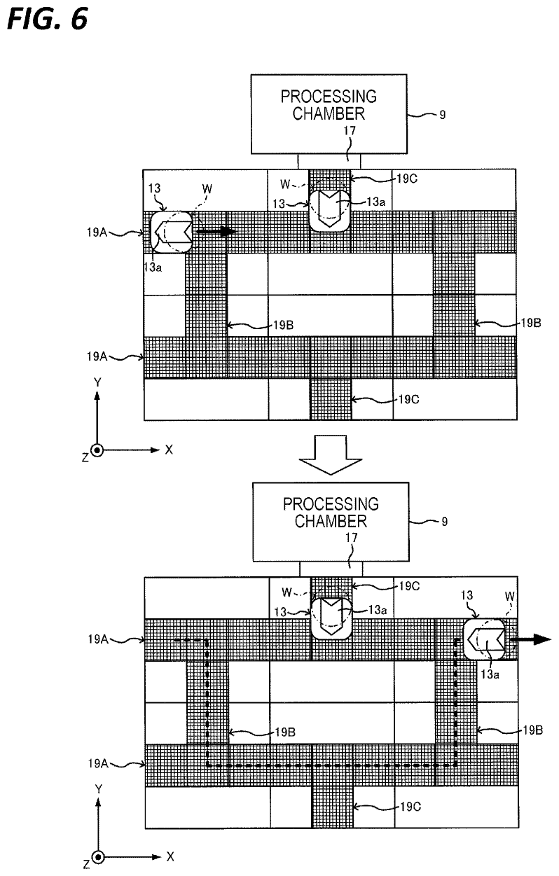

FIG. 6 illustrates an example of the operation control when a moving mover 13 bypasses another mover 13. When another mover 13 is present in front of a mover 13 moving on the upper-side first transfer path 19A (e.g., an example of one first transfer path) as illustrated in the upper view of FIG. 6, the controller 15 controls the moving mover 13 to move to the lower-side first transfer path 19A (e.g., an example of the other first transfer path) via the second transfer path 19B, thereby bypassing the another mover 13, as illustrated in the lower view of FIG. 6. The another mover 13 may be either in a moving state or a stopped state. The another mover 13 may include, for example, a mover 13 that is loading/unloading (putting/getting) the semiconductor substrate W into/out of a processing chamber 9, or a mover 13 that has become immovable due to a failure or the like.

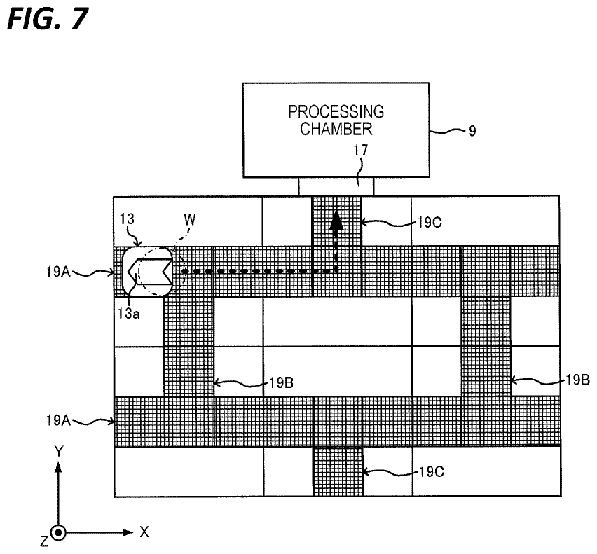

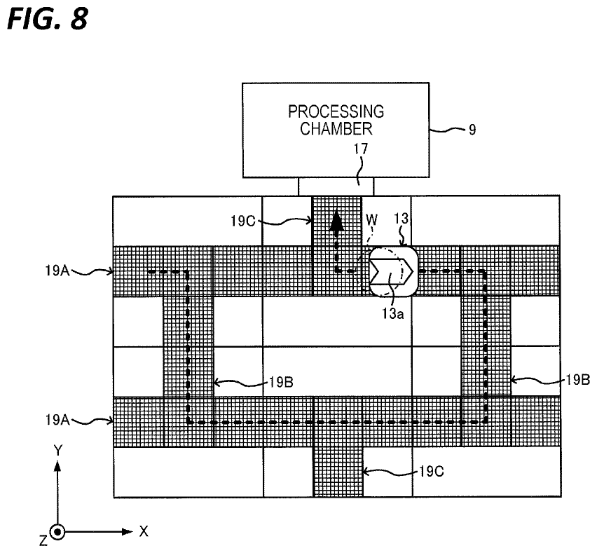

FIG. 7 illustrates an example of the operation control when a mover 13 is controlled to approach a specific processing chamber 9 from one side in the X-axis direction, and FIG. 8 illustrates an example of the operation control when a mover 13 is controlled to approach the specific processing chamber 9 from the other side in the X-axis direction. As illustrated in FIG. 7, when a mover 13 is moved toward the specific processing chamber 9 connected to the upper-side first transfer path 19A (e.g., an example of one first transfer path), the controller 15 controls the mover 13 to move toward the specific processing chamber 9 from the left side on the upper-side first transfer path 19A (e.g., an example of one side in a first direction). Further, as illustrated in FIG. 8, when a mover 13 is moved toward the specific processing chamber 9 connected to the upper-side first transfer path 19A (e.g., an example of one first transfer path), the controller 15 controls the mover 13 to detour from the upper-side first transfer path 19A via the second transfer path 19B and the lower-side first transfer path 19A, thereby moving toward the specific processing chamber 9 from the right side on the upper-side first transfer path 19A (e.g., an example of the other side in the first direction).

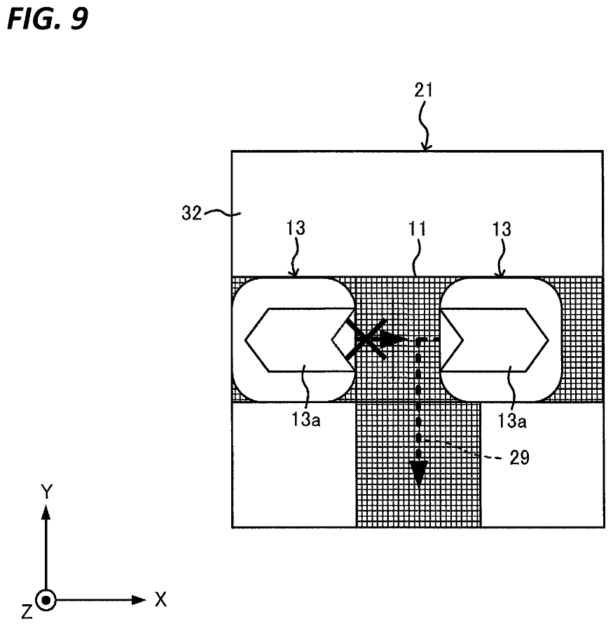

FIG. 9 illustrates an example of the operation control for preventing collision between movers 13. As illustrated in FIG. 9, the controller 15 controls the position of each mover 13 such that two or more movers 13 are not positioned on a single stator 11. In the example illustrated in FIG. 9, for example, since the mover 13 on the right side is moving along an arrow 29, and a portion thereof is positioned on the central stator 11 of the stator unit 21, the mover 13 on the left side is prohibited from moving onto the central stator 11. In this case, when the mover 13 on the right side moves along the arrow 29 and passes through the central stator 11 so that the entirety (including any portion) of the mover 13 on the right side is no longer positioned on the central stator 11, the mover 13 on the left side is permitted to move onto the central stator 11.

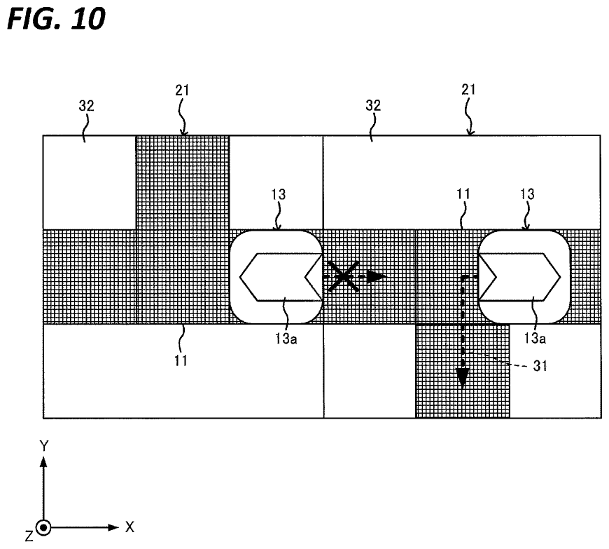

FIG. 10 illustrates another example of the operation control for preventing collision between movers 13. As illustrated in FIG. 10, the controller 15 may control the position of each mover 13 such that two or more movers 13 are not positioned on a single stator unit 21 (e.g., base 32). In the example illustrated in FIG. 10, for example, since the mover 13 on the right side is moving along an arrow 31, and a portion thereof is positioned on the central stator 11 of the right stator unit 21, the mover 13 on the left stator unit 21 is prohibited from moving onto the right stator unit 11. In this case, when the mover 13 on the right side moves along the arrow 31 and passes through the right stator unit 21 so that the entirety (including any portion) of the mover 13 on the right side is no longer positioned on the right stator unit 21, the mover 13 on the left side is permitted to move onto the right stator unit 21.

### 3. Configuration of Stator Unit

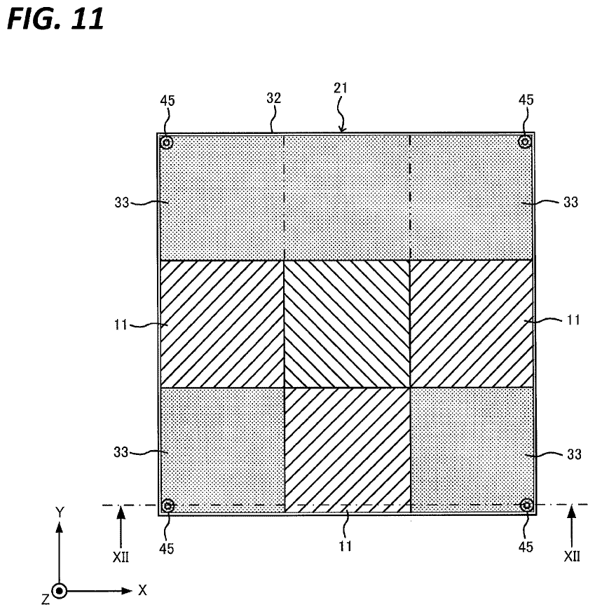

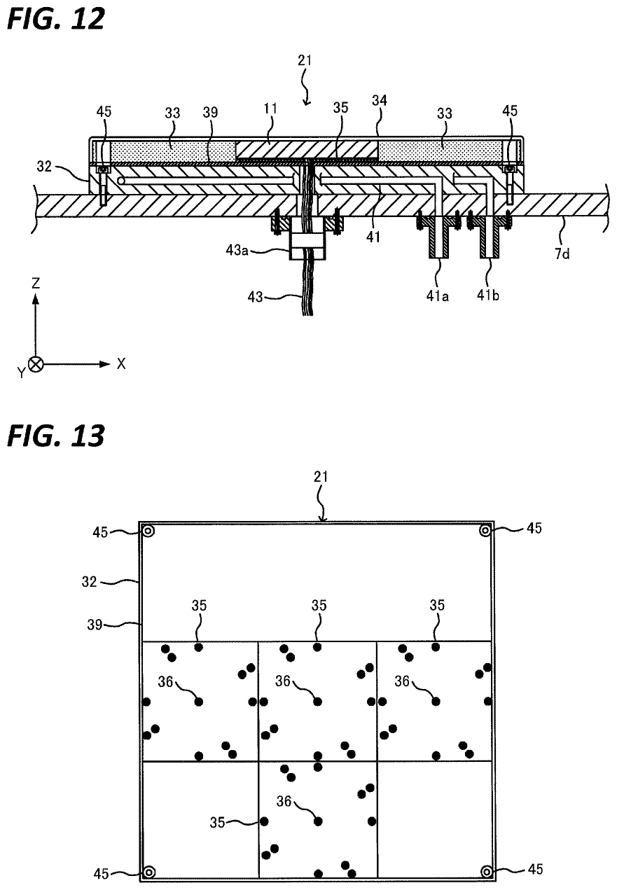

Next, an example of the configuration of the stator unit 21 will be described with reference to FIGS. 11 to 15. FIG. 11 is a plan view illustrating an example of the configuration of the stator unit 21 when viewed from above, and FIG. 12 is a cross-sectional view illustrating an example of the cross-sectional structure of the stator unit 21, which corresponds to the XII-XII cross section in FIG. 11. FIG. 11 omits illustration of a covering member 34 of the stator unit 21.

As illustrated in FIGS. 11 and 12, the stator unit 21 is configured as a unit including the base 32 having a larger area than the stator 11 when viewed from above in the Z-axis direction, and the plurality of stators 11 (e.g., four in the example illustrated in FIG. 11) arranged on the upper surface of the base 32. The stator unit 21 is configured such that the four stators 11 are arranged adjacent to each other on the upper surface of the base 32. The base 32 is formed in a substantially quadrangular shape when viewed from the Z-axis direction. The upper surface of the base 32 is divided into nine regions by being equally divided into three regions in both the longitudinal direction and the transverse direction, and the plurality of stators 11 are arranged in predetermined regions among the nine regions. In the example illustrated in FIG. 11, the four stators 11 are arranged in four regions among the nine regions, while being in contact with the edges of three sides of the four sides of the base 32 when viewed from the Z-axis direction. Thus, the four stators 11 are arranged in a substantially T shape. A resin 33 is filled in the regions of the upper surface of the base 32 other than the stators 11, i.e., the five regions where no stators 11 are disposed.

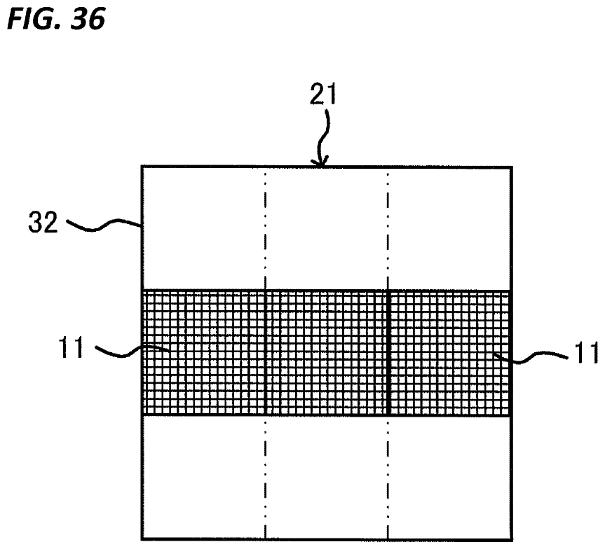

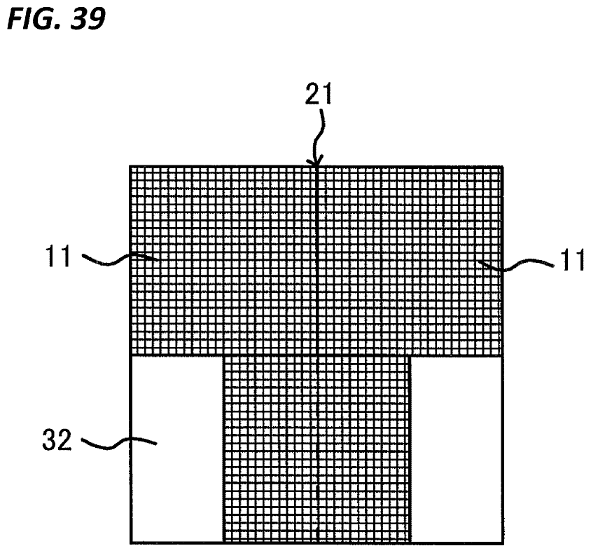

The number of divided regions of the upper surface of the base 32 is not limited to nine. The upper surface of the base 32 may be divided into, for example, four regions by being equally divided into two regions in both the longitudinal direction and the transverse direction (see, e.g., FIGS. 39 to 41 to be described herein later), or may be divided into, for example, 16 regions by being equally divided into four regions in both the longitudinal direction and the transverse direction. Further, the number of divided regions may differ between the longitudinal direction and the transverse direction. Further, the arrangement of the stators 11 is not limited to the T-shape, and the stators 11 may be arranged in contact with the edges of at least two sides of the four sides of the base 32 (see, e.g., FIGS. 36 to 38 to be described herein later).

The transfer path 19 illustrated in FIG. 1 is formed by connecting the plurality of stator units 21. For example, in the example illustrated in FIG. 1, the transfer path 19 is formed such that the stator units 21 each including the four stators 11 arranged in the substantially T shape are arranged along the X-axis direction in an alternating manner between a posture in which one stator 11 protrudes toward the negative side of the Y-axis direction, and a posture in which one stator 11 protrudes toward the positive side of the Y-axis direction, and further, the stator 11 protruding toward the negative side of the Y-axis direction and the stator 11 protruding toward the positive side of the Y-axis direction are arranged adjacent to (e.g., facing) each other in the Y-axis direction.

As illustrated in FIG. 12, each stator unit 21 includes the covering member 34 that covers the plurality of stators 11 arranged on the upper surface of the base 32, and the resin 33. The covering member 34 is formed of, for example, a nonmagnetic material such as stainless steel. The covering member 34 is formed in a quadrangular shape having substantially the same size as the base 32 when viewed from the Z-axis direction. The lower ends of the four sides of the covering member 34 are fixed to the upper surface of the base 32 through, for example, welding, to seal the inside of the covering member 34.

Further, as illustrated in FIG. 12, the stator unit 21 includes sensor substrates 35 disposed between the base 32 and the stators 11. In each sensor substrate 35, at least one sensor 36 is mounted to detect the position of the mover 13.

FIG. 13 illustrates an example of an arrangement of the sensor substrates and the sensors in the stator unit 21. As illustrated in FIG. 13, the sensor substrates 35 are each formed in the quadrangular shape having substantially the same size as the stator 11 when viewed from the Z-axis direction, and are disposed in the four regions where the stators 11 are arranged, respectively. A plurality of sensors 36 is disposed at predetermined positions in each sensor substrate 35. The number and arrangement of the sensors 36 illustrated in FIG. 13 are merely examples, and may be the number and arrangement other than the examples. The type of the sensors 36 is not particularly limited, and for example, Hall devices may be used.

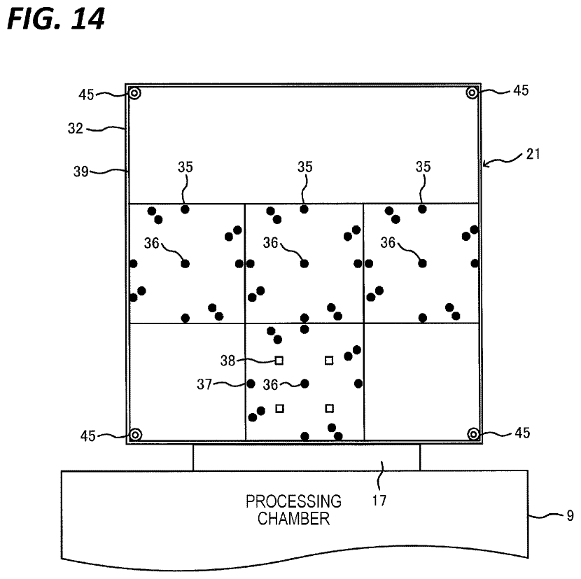

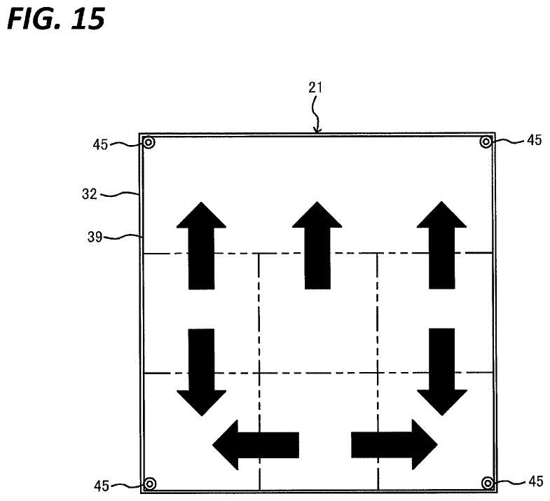

FIG. 14 illustrates another example of the arrangement of the sensor substrates and the sensors in the stator unit 21. In the example illustrated in FIG. 14, a sensor substrate 37 different from the sensor substrates 35 is disposed in the region where the stator 11 connected to a processing chamber 9 is disposed. In this region, loading/unloading (e.g., putting/getting) the semiconductor substrate W between the mover 13 and the processing chamber 9 are performed, and therefore, in addition to the sensors 36, sensors 38 are disposed at predetermined positions in the sensor substrate 37 to detect the position of the mover 13 with higher accuracy. That is, the stator unit 21 is configured such that the number of sensors in the region where the stator 11 connected to the processing chamber 9 is disposed is greater than the number of sensors in the region where the stator 11 that is not connected to the processing chamber 9 is disposed. The sensors 38 may be the same type of sensors as the sensors 36, or may be a different type of sensors achieving higher detection accuracy than the sensors 36. Further, the number and arrangement of the sensors 36 and 38 illustrated in FIG. 14 are merely examples, and may be the number and arrangement other than the examples.

As illustrated in FIG. 1, in the vacuum transfer chamber 7, a first stator unit 21A is disposed which includes the stator 11 connected to a processing chamber 9 (the stator unit 21 disposed to face the processing chamber 9 in the Y-axis direction), and a second stator unit 21B is disposed which does not include the stator 11 connected to a processing chamber 9 (e.g., the stator unit 21 disposed between adjacent processing chambers 9 in the X-axis direction). The arrangement of sensors in both the first stator unit 21A and the second stator unit 21B may be the same as the arrangement illustrated in FIG. 13. Alternatively, the arrangement of sensors in the first stator unit 21A may be the same as the arrangement illustrated in FIG. 14, and the arrangement of sensors in the second stator unit 21B may be the same as the arrangement illustrated in FIG. 13. In this case, the number of sensors in the first stator unit 21A connected to the processing chamber 9 is greater than the number of sensors in the second stator unit 21B that is not connected to the processing chamber 9.

Further, as illustrated in FIG. 12, the stator unit 21 includes a heat transfer member 39 disposed between the base 32 and the stators 11 to transfer heat generated by the stator 11 to the base 32. The material of the heat transfer member 39 is not particularly limited, and may be, for example, a metal plate (e.g., aluminum or copper) or a heat pipe. FIG. 15 illustrates an example of the direction of heat transfer by the heat transfer member 39. As illustrated in FIG. 15, the heat transfer member 39 is formed in a substantially quadrangular shape having substantially the same size as the base 32 when viewed from the Z-axis direction. As indicated by arrows in FIG. 15, the heat generated by each stator 11 is transferred from the four regions where the stators 11 are disposed toward the surrounding regions in the heat transfer member 39, thereby spreading throughout the entire heat transfer member 39. As a result, the heat generated by the stators 11 is efficiently transferred from the heat transfer member 39 to the base 32.

As illustrated in FIG. 12, a cooling liquid pipe 41 is provided inside the base 32, and a cooling liquid is introduced through a cooling liquid inlet 41a and discharged through a cooling liquid outlet 41b. Accordingly, the heat transferred from the heat transfer member 39 to the base 32 may be more efficiently cooled. The cooling liquid pipe 41 may not be provided in the base 32.

As illustrated in FIGS. 11 and 12, the base 32 is fixed to the bottom 7d of the vacuum transfer chamber 7, for example, at four locations corresponding to its four corners, by bolts 45. In each of the regions of the base 32 and the bottom 7d where the stators 11 are disposed, a through hole is provided to route a stator wire 43, and the stator wire 43 is connected to the stator 11 via a wire introduction terminal 43a. Although not illustrated, in each of the regions of the base 32 and the bottom 7d where the sensor substrates 35 and 37 are disposed, a through hole is provided to route sensor wires, and the sensor wires are connected to the sensor substrates 35 and 37 via wire introduction terminals.

### 4. Configuration of Coil Unit

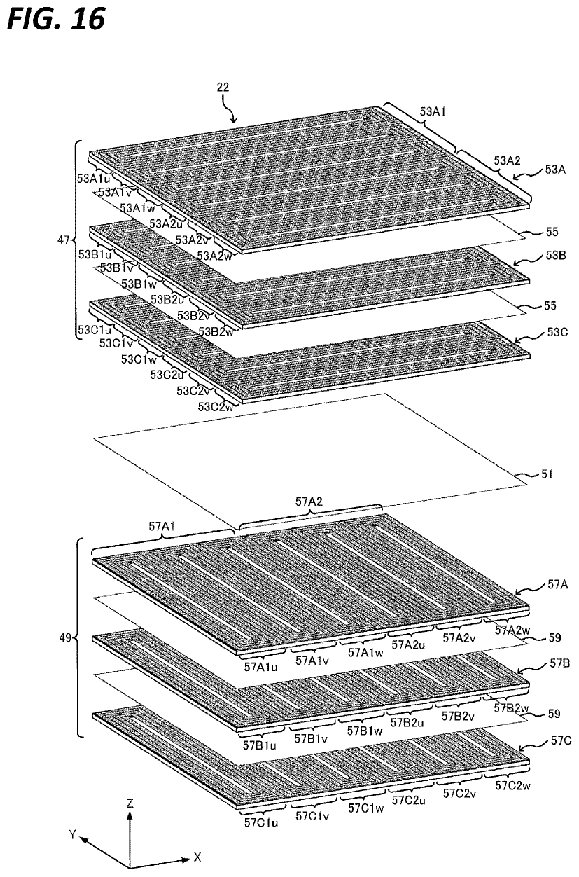

Next, an example of the configuration of the coil unit 22 included in the stator 11 will be described with reference to FIGS. 16 to 26. FIGS. 16 to 18 and 21 to 26 illustrate the substrate coils in a simplified manner by reducing the number of windings (e.g., turns).

FIG. 16 illustrates an example of a layer configuration of the coil unit 22. As illustrated in FIG. 16, the coil unit 22 includes a first substrate coil unit 47 and a second substrate coil unit 49. The first substrate coil unit 47 and the second substrate coil unit 49 are stacked in the Z-axis direction via, for example, an insulating layer 51. The first substrate coil unit 47 has its longitudinal direction following the X-axis direction, and the second substrate coil unit 49 has its longitudinal direction following the Y-axis direction. The first substrate coil unit 47 is configured as a multilayer substrate, and is also configured as a coil unit in which a plurality of first substrate coils 53A, 53B, and 53C (e.g., three layers in the example illustrated in FIG. 16) and a plurality of insulating layers 55 (e.g., two layers in the example illustrated in FIG. 16) disposed between the first substrate coils are stacked in the Z-axis direction and integrated. The second substrate coil unit 49 is configured as a multilayer substrate, and is also configured as a coil unit in which a plurality of second substrate coils 57A, 57B, and 57C (e.g., three layers in the example illustrated in FIG. 16) and a plurality of insulating layers 59 (e.g., two layers in the example illustrated in FIG. 16) disposed between the second substrate coils are stacked in the Z-axis direction and integrated.

The first substrate coil 53A includes two sets of first substrate coils 53A1 and 53A2. The first substrate coils 53A1 and 53A2 are arranged adjacent to each other along the Y-axis direction. The first substrate coil 53A1 includes a first substrate coil 53A1u corresponding to the U phase, a first substrate coil 53A1v corresponding to the V phase, and a first substrate coil 53A1w corresponding to the W phase. The first substrate coils 53A1u, 53A1v, and 53A1w are arranged adjacent to each other along the Y-axis direction. Similarly, the first substrate coil 53A2 includes a first substrate coil 53A2u corresponding to the U phase, a first substrate coil 53A2v corresponding to the V phase, and a first substrate coil 53A2w corresponding to the W phase. The first substrate coils 53A2u, 53A2v, and 53A2w are arranged adjacent to each other along the Y-axis direction.

The first substrate coil 53B includes two sets of first substrate coils 53B1 and 53B2 (the reference numerals are omitted in FIG. 16). The first substrate coils 53B1 and 53B2 are arranged adjacent to each other along the Y-axis direction. The first substrate coil 53B1 includes a first substrate coil 53B1u corresponding to the U phase, a first substrate coil 53B1v corresponding to the V phase, and a first substrate coil 53B1w corresponding to the W phase. The first substrate coils 53B1u, 53B1v, and 53B1w are arranged adjacent to each other along the Y-axis direction. Similarly, the first substrate coil 53B2 includes a first substrate coil 53B2u corresponding to the U phase, a first substrate coil 53B2v corresponding to the V phase, and a first substrate coil 53B2w corresponding to the W phase. The first substrate coils 53B2u, 53B2v, and 53B2w are arranged adjacent to each other along the Y-axis direction.

The first substrate coil 53C includes two sets of first substrate coils 53C1 and 53C2 (the reference numerals are omitted in FIG. 16). The first substrate coils 53C1 and 53C2 are arranged adjacent to each other along the Y-axis direction. The first substrate coil 53C1 includes a first substrate coil 53C1u corresponding to the U phase, a first substrate coil 53C1v corresponding to the V phase, and a first substrate coil 53C1w corresponding to the W phase. The first substrate coils 53C1u, 53C1v, and 53C1w are arranged adjacent to each other along the Y-axis direction. Similarly, the first substrate coil 53C2 includes a first substrate coil 53C2u corresponding to the U phase, a first substrate coil 53C2v corresponding to the V phase, and a first substrate coil 53C2w corresponding to the W phase. The first substrate coils 53C2u, 53C2v, and 53C2w are arranged adjacent to each other along the Y-axis direction.

The second substrate coil 57A includes two sets of second substrate coils 57A1 and 57A2. The second substrate coils 57A1 and 57A2 are arranged adjacent to each other along the X-axis direction. The second substrate coil 57A1 includes a second substrate coil 57A1u corresponding to the U phase, a second substrate coil 57A1v corresponding to the V phase, and a second substrate coil 57A1w corresponding to the W phase. The second substrate coils 57A1u, 57A1v, and 57A1w are arranged adjacent to each other along the X-axis direction. Similarly, the second substrate coil 57A2 includes a second substrate coil 57A2u corresponding to the U phase, a second substrate coil 57A2v corresponding to the V phase, and a second substrate coil 57A2w corresponding to the W phase. The second substrate coils 57A2u, 57A2v, and 57A2w are arranged adjacent to each other along the X-axis direction.

The second substrate coil 57B includes two sets of second substrate coils 57B1 and 57B2 (the reference numerals are omitted in FIG. 16). The second substrate coils 57B1 and 57B2 are arranged adjacent to each other along the X-axis direction. The second substrate coil 57B1 includes a second substrate coil 57B1u corresponding to the U phase, a second substrate coil 57B1v corresponding to the V phase, and a second substrate coil 57B1w corresponding to the W phase. The second substrate coils 57B1u, 57B1v, and 57B1w are arranged adjacent to each other along the X-axis direction. Similarly, the second substrate coil 57B2 includes a second substrate coil 57B2u corresponding to the U phase, a second substrate coil 57B2v corresponding to the V phase, and a second substrate coil 57B2w corresponding to the W phase. The second substrate coils 57B2u, 57B2v, and 57B2w are arranged adjacent to each other along the X-axis direction.

The second substrate coil 57C includes two sets of second substrate coils 57C1 and 57C2 (the reference numerals are omitted in FIG. 16). The second substrate coils 57C1 and 57C2 are arranged adjacent to each other along the X-axis direction. The second substrate coil 57C1 includes a second substrate coil 57C1u corresponding to the U phase, a second substrate coil 57C1v corresponding to the V phase, and a second substrate coil 57C1w corresponding to the W phase. The second substrate coils 57C1u, 57C1v, and 57C1w are arranged adjacent to each other along the X-axis direction. Similarly, the second substrate coil 57C2 includes a second substrate coil 57C2u corresponding to the U phase, a second substrate coil 57C2v corresponding to the V phase, and a second substrate coil 57C2w corresponding to the W phase. The second substrate coils 57C2u, 57C2v, and 57C2w are arranged adjacent to each other along the X-axis direction.

The first substrate coil unit 47 or the second substrate coil unit 49 may have a configuration other than the three-layer configuration. For example, the first substrate coil unit 47 or the second substrate coil unit 49 may have a single-layer configuration including single-layer substrate coils, or a configuration of multiple-layer substrates other than three layers. In the descriptions above, the U-phase, V-phase, and W-phase substrate coils make up one set, and two sets of substrate coils are arranged in parallel. However, a single set of substrate coils may be provided, or three or more sets of substrate coils may be arranged in parallel.

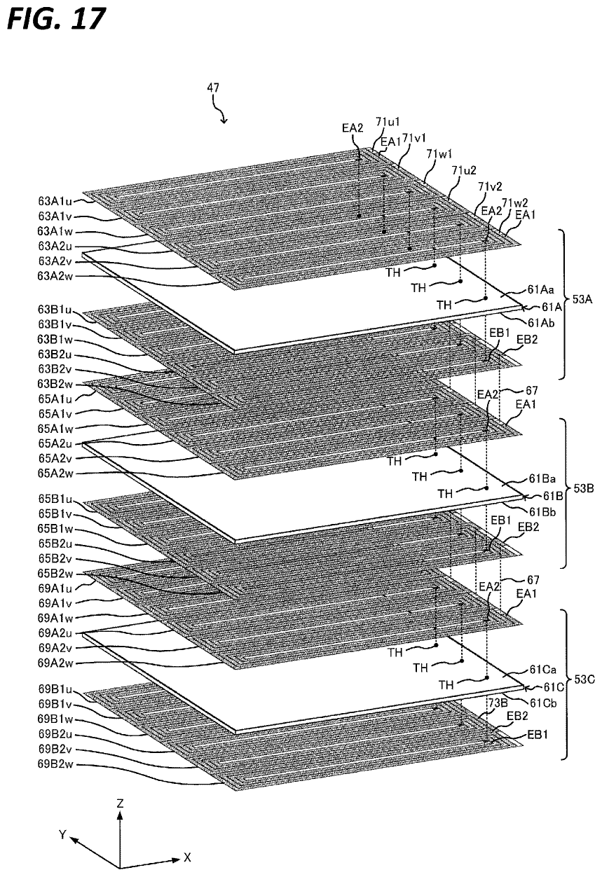

FIG. 17 illustrates an example of the layer configuration of the first substrate coil unit 47. FIG. 17 omits illustration of the insulating layers 55. As illustrated in FIG. 17, the first substrate coils 53A, 53B, and 53C included in the first substrate coil unit 47 include first substrates 61A, 61B, and 61C, respectively, formed of an insulating material (e.g., resin), and first coil patterns formed on both the front and rear surfaces of the first substrates 61A, 61B, and 61C. That is, the first substrate coils 53A, 53B, and 53C are printed substrates in which the first coil patterns are formed as wiring patterns on the first substrates 61A, 61B, and 61C through a printing technology. The printing technology includes, for example, forming a thin film such as copper foil on a substrate, applying a photoresist thereon, exposing formed coil patterns, and then, removing an unnecessary thin film by etching.

The first substrate coil 53A is configured such that substantially rectangular spiral-shaped first coil patterns 63A1u, 63A1v, 63A1w, 63A2u, 63A2v, and 63A2w each having its longitudinal direction following the X-axis direction are formed on the front surface 61Aa of the first substrate 61A (the upper surface in the Z-axis direction; an example of a first surface), and first coil patterns 63B1u, 63B1v, 63B1w, 63B2u, 63B2v, and 63B2w are formed on the rear surface 61Ab of the first substrate 61A (the lower surface in the Z-axis direction; an example of a second surface). The first substrate 61A may be divided for each set including three U, V, and W phases, or may be divided for each of the U, V, and W phases. The X-axis direction refers to the direction along the front surface 61Aa or the rear surface 61Ab of the first substrate 61A.

The first coil pattern 63A1u is formed in a substantially rectangular spiral shape having its longitudinal direction following the X-axis direction, such that the start terminal EA1 thereof in a current flow direction (e.g., an example of one terminal) is disposed near the edge of the first substrate coil 53A1u (see, e.g., FIG. 16), and the end terminal EA2 thereof (e.g., an example of the other terminal) is disposed near the center position of the first substrate coil 53A1u in the Y-axis direction. The first coil pattern 63A1u has a clockwise spiral shape with respect to the current flow direction as viewed from above in the Z-axis direction. The first coil pattern 63B1u is formed in a region overlapping with the first coil pattern 63A1u as viewed from the Z-axis direction. The first coil pattern 63B1u is formed in a substantially rectangular spiral shape having its longitudinal direction following the X-axis direction, such that the start terminal EB1 thereof in the current flow direction is disposed near the center position of the first substrate coil 53A1u in the Y-axis direction, and the end terminal EB2 thereof is disposed near the edge of the first substrate coil 53A1u. The first coil pattern 63B1u has a clockwise spiral shape with respect to the current flow direction as viewed from above in the Z-axis direction. The first coil patterns 63A1u and 33B1u are formed such that their wiring patterns overlap with each other as viewed from the Z-axis direction. The end terminal EA2 of the first coil pattern 63A1u and the start terminal EB1 of the first coil pattern 63B1u are electrically connected via a through hole TH penetrating the first substrate 61A. With the first coil patterns 63A1u and 63B1u and the first substrate 61A configured as described above, the concentrated winding first substrate coil 53A1u (see, e.g., FIG. 16) is formed.

The first coil patterns 63A1v and 63B1v are also configured in the same manner as the first coil patterns 63A1u and 63B1u described above. With the first coil patterns 63A1v and 63B1v and the first substrate 61A, the concentrated winding first substrate coil 53A1v (see, e.g., FIG. 16) is formed. The first coil patterns 63A1w and 63B1w are also configured in the same manner as the first coil patterns 63A1u and 63B1u described above. With the first coil patterns 63A1w and 63B1w and the first substrate 61A, the concentrated winding first substrate coil 53A1w (see, e.g., FIG. 16) is formed. The first coil patterns 63A2u and 63B2u are also configured in the same manner as the first coil patterns 63A1u and 63B1u described above. With the first coil patterns 63A2u and 63B2u and the first substrate 61A, the concentrated winding first substrate coil 53A2u (see, e.g., FIG. 16) is formed. The first coil patterns 63A2v and 63B2v are also configured in the same manner as the first coil patterns 63A1u and 63B1u described above. With the first coil patterns 63A2v and 63B2v and the first substrate 61A, the concentrated winding first substrate coil 53A2v (see, e.g., FIG. 16) is formed. The first coil patterns 63A2w and 63B2w are also configured in the same manner as the first coil patterns 63A1u and 63B1u described above. With the first coil patterns 63A2w and 63B2w and the first substrate 61A, the concentrated winding first substrate coil 53A2w (see, e.g., FIG. 16) is formed.

The first substrate coil 53B is configured such that substantially rectangular spiral-shaped first coil patterns 65A1u, 65A1v, 65A1w, 65A2u, 65A2v, and 65A2w each having its longitudinal direction following the X-axis direction are formed on the front surface 61Ba of the first substrate 61B (the upper surface in the Z-axis direction; an example of a first surface), and first coil patterns 65B1u, 65B1v, 65B1w, 65B2u, 65B2v, and 65B2w are formed on the rear surface 61Bb of the first substrate 61B (the lower surface in the Z-axis direction; an example of a second surface). The first substrate 61B may be divided for each set including three U, V, and W phases, or may be divided for each of the U, V, and W phases. The X-axis direction refers to the direction along the front surface 61Ba or the rear surface 61Bb of the first substrate 61B.

The first coil patterns 65A1u and 65B1u are also configured in the same manner as the first coil patterns 63A1u and 63B1u described above. With the first coil patterns 65A1u and 65B1u and the first substrate 61B, the concentrated winding first substrate coil 53B1u (see, e.g., FIG. 16) is formed. The first coil patterns 65A1v and 65B1v are also configured in the same manner as the first coil patterns 63A1u and 63B1u described above. With the first coil patterns 65A1v and 65B1v and the first substrate 61B, the concentrated winding first substrate coil 53B1v (see, e.g., FIG. 16) is formed. The first coil patterns 65A1w and 65B1w are also configured in the same manner as the first coil patterns 63A1u and 63B1u described above. With the first coil patterns 65A1w and 65B1w and the first substrate 61B, the concentrated winding first substrate coil 53B1w (see, e.g., FIG. 16) is formed. The first coil patterns 65A2u and 65B2u are also configured in the same manner as the first coil patterns 63A1u and 63B1u described above. With the first coil patterns 65A2u and 65B2u and the first substrate 61B, the concentrated winding first substrate coil 53B2u (see, e.g., FIG. 16) is formed. The first coil patterns 65A2v and 65B2v are also configured in the same manner as the first coil patterns 63A1u and 63B1u described above. With the first coil patterns 65A2v and 65B2v and the first substrate 61B, the concentrated winding first substrate coil 53B2v (see, e.g., FIG. 16) is formed. The first coil patterns 65A2w and 65B2w are also configured in the same manner as the first coil patterns 63A1u and 63B1u described above. With the first coil patterns 65A2w and 65B2w and the first substrate 61B, the concentrated winding first substrate coil 53B2w (see, e.g., FIG. 16) is formed.

The end terminal EB2 of the first coil pattern 63B1u of the first substrate coil 53A and the start terminal EA1 of the first coil pattern 65A1u of the first substrate coil 53B are electrically connected by a connection line 67. Similarly, the end terminal EB2 of the first coil pattern 63B1v of the first substrate coil 53A and the start terminal EA1 of the first coil pattern 65A1v of the first substrate coil 53B are electrically connected by a connection line 67. Similarly, the end terminal EB2 of the first coil pattern 63B1w of the first substrate coil 53A and the start terminal EA1 of the first coil pattern 65A1w of the first substrate coil 53B are electrically connected by a connection line 67. Similarly, the end terminal EB2 of the first coil pattern 63B2u of the first substrate coil 53A and the start terminal EA1 of the first coil pattern 65A2u of the first substrate coil 53B are electrically connected by a connection line 67. Similarly, the end terminal EB2 of the first coil pattern 63B2v of the first substrate coil 53A and the start terminal EA1 of the first coil pattern 65A2v of the first substrate coil 53B are electrically connected by a connection line 67. Similarly, the end terminal EB2 of the first coil pattern 63B2w of the first substrate coil 53A and the start terminal EA1 of the first coil pattern 65A2w of the first substrate coil 53B are electrically connected by a connection line 67. The connection lines 67 may be provided within or outside the first substrate coils 53A and 53B in the XY-plane direction.

The first substrate coil 53C is configured such that substantially rectangular spiral-shaped first coil patterns 69A1u, 69A1v, 69A1w, 69A2u, 69A2v, and 69A2w each having its longitudinal direction following the X-axis direction are formed on the front surface 61Ca of the first substrate 61C (the upper surface in the Z-axis direction; an example of a first surface), and first coil patterns 69B1u, 69B1v, 69B1w, 69B2u, 69B2v, and 69B2w are formed on the rear surface 61Cb of the first substrate 61C (the lower surface in the Z-axis direction; an example of a second surface). The first substrate 61C may be divided for each set including three U, V, and W phases, or may be divided for each of the U, V, and W phases. The X-axis direction refers to the direction along the front surface 61Ca or the rear surface 61Cb of the first substrate 61C.

The first coil patterns 69A1u and 69B1u are also configured in the same manner as the first coil patterns 63A1u and 63B1u described above. With the first coil patterns 69A1u and 69B1u and the first substrate 61C, the concentrated winding first substrate coil 53C1u (see, e.g., FIG. 16) is formed. The first coil patterns 69A1v and 69B1v are also configured in the same manner as the first coil patterns 63A1u and 63B1u described above. With the first coil patterns 69A1v and 69B1v and the first substrate 61C, the concentrated winding first substrate coil 53C1v (see, e.g., FIG. 16) is formed. The first coil patterns 69A1w and 69B1w are also configured in the same manner as the first coil patterns 63A1u and 63B1u described above. With the first coil patterns 69A1w and 69B1w and the first substrate 61C, the concentrated winding first substrate coil 53C1w (see, e.g., FIG. 16) is formed. The first coil patterns 69A2u and 69B2u are also configured in the same manner as the first coil patterns 63A1u and 63B1u described above. With the first coil patterns 69A2u and 69B2u and the first substrate 61C, the concentrated winding first substrate coil 53C2u (see, e.g., FIG. 16) is formed. The first coil patterns 69A2v and 69B2v are also configured in the same manner as the first coil patterns 63A1u and 63B1u described above. With the first coil patterns 69A2v and 69B2v and the first substrate 61C, the concentrated winding first substrate coil 53C2v (see, e.g., FIG. 16) is formed. The first coil patterns 69A2w and 69B2w are also configured in the same manner as the first coil patterns 63A1u and 63B1u described above. With the first coil patterns 69A2w and 69B2w and the first substrate 61C, the concentrated winding first substrate coil 53C2w (see, e.g., FIG. 16) is formed.

The end terminal EB2 of the first coil pattern 65B1u of the first substrate coil 53B and the start terminal EA1 of the first coil pattern 69A1u of the first substrate coil 53C are electrically connected by a connection line 67. Similarly, the end terminal EB2 of the first coil pattern 65B1v of the first substrate coil 53B and the start terminal EA1 of the first coil pattern 69A1v of the first substrate coil 53C are electrically connected by a connection line 67. Similarly, the end terminal EB2 of the first coil pattern 65B1w of the first substrate coil 53B and the start terminal EA1 of the first coil pattern 69A1w of the first substrate coil 53C are electrically connected by a connection line 67. Similarly, the end terminal EB2 of the first coil pattern 65B2u of the first substrate coil 53B and the start terminal EA1 of the first coil pattern 69A2u of the first substrate coil 53C are electrically connected by a connection line 67. Similarly, the end terminal EB2 of the first coil pattern 65B2v of the first substrate coil 53B and the start terminal EA1 of the first coil pattern 69A2v of the first substrate coil 53C are electrically connected by a connection line 67. Similarly, the end terminal EB2 of the first coil pattern 65B2w of the first substrate coil 53B and the start terminal EA1 of the first coil pattern 69A2w of the first substrate coil 53C are electrically connected by a connection line 67. The connection lines 67 may be provided within or outside the first substrate coils 53B and 53C in the XY-plane direction.

The first substrate coil unit 47 includes first current inflow portions 71u1, 71v1, 71w1, 71u2, 71v2, and 71w2, through which current flows into the first substrate coils. The first current inflow portions 71u1, 71v1, 71w1, 71u2, 71v2, and 71w2 are arranged collectively at the end of the positive side in the X-axis direction (e.g., an example of one side). For example, the first current inflow portion 71u1 is connected to the start terminal EA1 of the first coil pattern 63A1u, on the front surface 61Aa of the first substrate 61A. The first current inflow portion 71v1 is connected to the start terminal EA1 of the first coil pattern 63A1v, on the front surface 61Aa of the first substrate 61A. The first current inflow portion 71w1 is connected to the start terminal EA1 of the first coil pattern 63A1w, on the front surface 61Aa of the first substrate 61A. The first current inflow portion 71u2 is connected to the start terminal EA1 of the first coil pattern 63A2u, on the front surface 61Aa of the first substrate 61A. The first current inflow portion 71v2 is connected to the start terminal EA1 of the first coil pattern 63A2v, on the front surface 61Aa of the first substrate 61A. The first current inflow portion 71w2 is connected to the start terminal EA1 of the first coil pattern 63A2w, on the front surface 61Aa of the first substrate 61A.

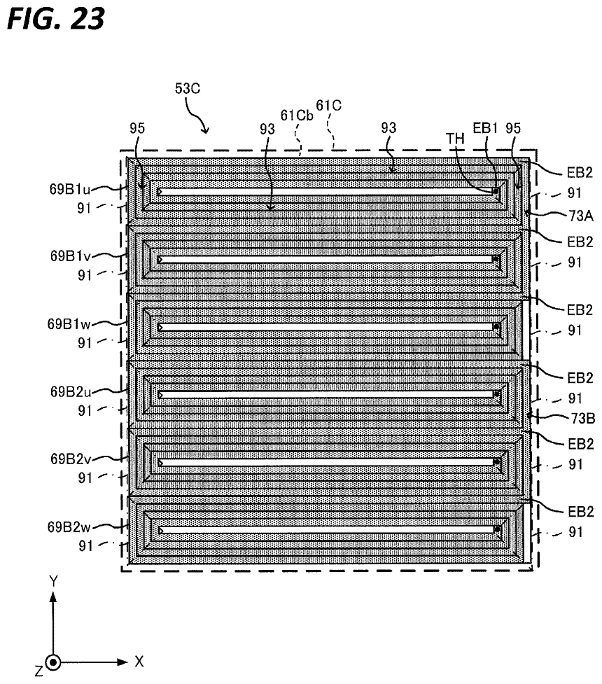

The first substrate coil unit 47 includes first neutral points 73A and 73B (see also, e.g., FIG. 23) to connect the plurality of first substrate coils having different phases (e.g., three U, V, and W phases). The first neutral points 73A and 73B are arranged collectively at the end of the positive side in the X-axis direction (e.g., an example of one side). For example, the first neutral point 73A connects each of the end terminal EB2 of the first coil pattern 69B1u, the end terminal EB2 of the first coil pattern 69B1v, and the end terminal EB2 of the first coil pattern 69B1w, on the rear surface 61Cb of the first substrate 61C (see also, e.g., FIG. 23). The first neutral point 73B connects each of the end terminal EB2 of the first coil pattern 69B2u, the end terminal EB2 of the first coil pattern 69B2v, and the end terminal EB2 of the first coil pattern 69B2w, on the rear surface 61Cb of the first substrate 61C (see also, e.g., FIG. 23).

With the configuration above, the current flowing in from the first current inflow portion 71u1 passes through the first coil patterns 63A1u, 63B1u, 65A1u, 65B1u, 69A1u, and 69B1u and flows into the first neutral point 73A, the current flowing in from the first current inflow portion 71v1 passes through the first coil patterns 63A1v, 63B1v, 65A1v, 65B1v, 69A1v, and 69B1v and flows into the first neutral point 73A, and the current flowing in from the first current inflow portion 71w1 passes through the first coil patterns 63A1w, 63B1w, 65A1w, 65B1w, 69A1w, and 69B1w and flows into the first neutral point 73A, which forms a star connection (e.g., Y-connection). Similarly, the current flowing in from the first current inflow portion 71u2 passes through the first coil patterns 63A2u, 63B2u, 65A2u, 65B2u, 69A2u, and 69B2u and flows into the first neutral point 73B, the current flowing in from the first current inflow portion 71v2 passes through the first coil patterns 63A2v, 63B2v, 65A2v, 65B2v, 69A2v, and 69B1v and flows into the first neutral point 73B, and the current flowing in from the first current inflow portion 71w2 passes through the first coil patterns 63A2w, 63B2w, 65A2w, 65B2w, 69A2w, and 69B2w and flows into the first neutral point 73B, which forms a star connection (Y-connection).

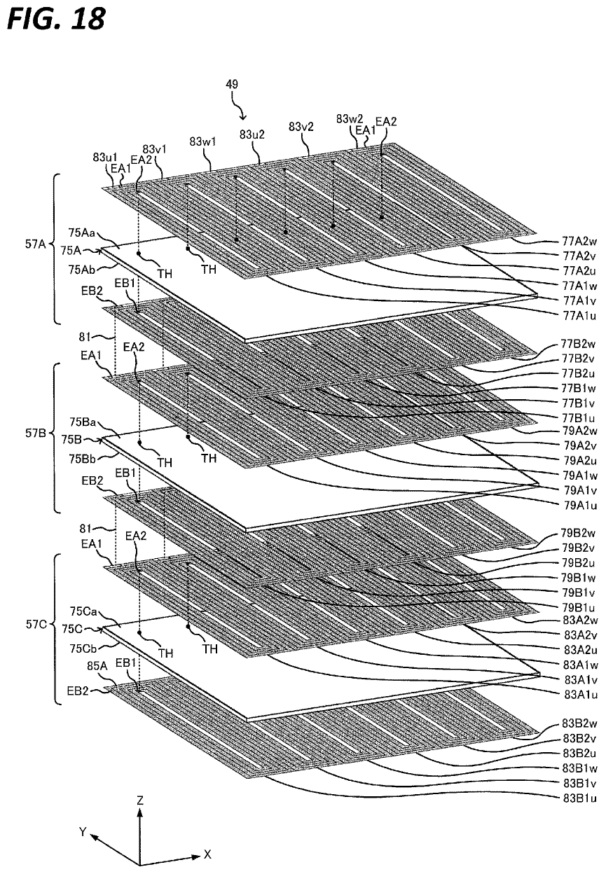

FIG. 18 illustrates an example of the layer configuration of the second substrate coil unit 49. FIG. 18 omits illustration of the insulating layers 59. As illustrated in FIG. 18, the second substrate coils 57A, 57B, and 57C included in the second substrate coil unit 49 include second substrates 75A, 75B, and 75C, respectively, formed of an insulating material (e.g., resin), and second coil patterns formed on both the front and rear surfaces of the second substrate 75A, 75B, or 75C. That is, the second substrate coils 57A, 57B, and 57C are printed substrates in which the second coil patterns are formed as wiring patterns on the second substrates 75A, 75B, and 75C through a printing technology. The printing technology includes, for example, forming a thin film such as copper foil on a substrate, applying a photoresist thereon, exposing formed coil patterns, and then, removing an unnecessary thin film by etching. The second substrates 75A, 75B, and 75C are different from the first substrates 61A, 61B, and 61C.

The second substrate coil 57A is configured such that substantially rectangular spiral-shaped second coil patterns 77A1u, 77A1v, 77A1w, 77A2u, 77A2v, and 77A2w each having its longitudinal direction following the Y-axis direction are formed on the front surface 75Aa of the second substrate 75A (the upper surface in the Z-axis direction; an example of a first surface), and second coil patterns 77B1u, 77B1v, 77B1w, 77B2u, 77B2v, and 77B2w are formed on the rear surface 75Ab of the first substrate 75A (the lower surface in the Z-axis direction; an example of a second surface). The second substrate 75A may be divided for each set including three U, V, and W phases, or may be divided for each of the U, V, and W phases. The Y-axis direction refers to the direction along the front surface 75Aa or the rear surface 75Ab of the second substrate 75A.

The second coil pattern 77A1u is formed in a substantially rectangular spiral shape having its longitudinal direction following the Y-axis direction, such that the start terminal EA1 thereof in the current flow direction (e.g., an example of one terminal) is disposed near the edge of the second substrate coil 57A1u (see, e.g., FIG. 16), and the end terminal EA2 thereof (e.g., an example of the other terminal) is disposed near the center position of the second substrate coil 57A1u in the X-axis direction. The second coil pattern 77A1u has a clockwise spiral shape with respect to the current flow direction as viewed from above in the Z-axis direction. The second coil pattern 77B1u is formed in a region overlapping with the second coil pattern 77A1u as viewed from the Z-axis direction. The second coil pattern 77B1u is formed in a substantially rectangular spiral shape having its longitudinal direction following the Y-axis direction, such that the start terminal EB1 thereof in the current flow direction is disposed near the center position of the second substrate coil 57A1u in the X-axis direction, and the end terminal EB2 thereof is disposed near the edge of the second substrate coil 57A1u. The second coil pattern 77B1u has a clockwise spiral shape with respect to the current flow direction as viewed from above in the Z-axis direction. The second coil patterns 77A1u and 77B1u are formed such that their wiring patterns overlap with each other as viewed from the Z-axis direction. The end terminal EA2 of the second coil pattern 77A1u and the start terminal EB1 of the second coil pattern 77B1u are electrically connected via a through hole TH penetrating the second substrate 75A. With the second coil patterns 77A1u and 77B1u and the second substrate 75A configured as described above, the concentrated winding second substrate coil 57A1u (see, e.g., FIG. 16) is formed.

The second coil patterns 77A1v and 77B1v are also configured in the same manner as the second coil patterns 77A1u and 77B1u described above. With the second coil patterns 77A1v and 77B1v and the second substrate 75A, the concentrated winding second substrate coil 57A1v (see, e.g., FIG. 16) is formed. The second coil patterns 77A1w and 77B1w are also configured in the same manner as the second coil patterns 77A1u and 77B1u described above. With the second coil patterns 77A1w and 77B1w and the second substrate 75A, the concentrated winding second substrate coil 57A1w (see, e.g., FIG. 16) is formed. The second coil patterns 77A2u and 77B2u are also configured in the same manner as the second coil patterns 77A1u and 77B1u described above. With the second coil patterns 77A2u and 77B2u and the second substrate 75A, the concentrated winding second substrate coil 57A2u (see, e.g., FIG. 16) is formed. The second coil patterns 77A2v and 77B2v are also configured in the same manner as the second coil patterns 77A1u and 77B1u described above. With the second coil patterns 77A2v and 77B2v and the second substrate 75A, the concentrated winding second substrate coil 57A2v (see, e.g., FIG. 16) is formed. The second coil patterns 77A2w and 77B2w are also configured in the same manner as the second coil patterns 77A1u and 77B1u described above. With the second coil patterns 77A2w and 77B2w and the second substrate 75A, the concentrated winding second substrate coil 57A2w (see, e.g., FIG. 16) is formed.

The second substrate coil 57B is configured such that substantially rectangular spiral-shaped second coil patterns 79A1u, 79A1v, 79A1w, 79A2u, 79A2v, and 79A2w each having its longitudinal direction following the Y-axis direction are formed on the front surface 75Ba of the second substrate 75B (e.g., the upper surface in the Z-axis direction; an example of a first surface), and second coil patterns 79B1u, 79B1v, 79B1w, 79B2u, 79B2v, and 79B2w are formed on the rear surface 75Bb of the second substrate 75B (e.g., the lower surface in the Z-axis direction; an example of a second surface). The second substrate 75B may be divided for each set including three U, V, and W phases, or may be divided for each of the U, V, and W phases. The Y-axis direction refers to the direction along the front surface 75Ba or the rear surface 75Bb of the second substrate 75B.

The second coil patterns 79A1u and 79B1u are also configured in the same manner as the second coil patterns 77A1u and 77B1u described above. With the second coil patterns 79A1u and 79B1u and the second substrate 75B, the concentrated winding second substrate coil 57B1u (see, e.g., FIG. 16) is formed. The second coil patterns 79A1v and 79B1v are also configured in the same manner as the second coil patterns 77A1u and 77B1u described above. With the second coil patterns 79A1v and 79B1v and the second substrate 75B, the concentrated winding second substrate coil 57B1v (see, e.g., FIG. 16) is formed. The second coil patterns 79A1w and 79B1w are also configured in the same manner as the second coil patterns 77A1u and 77B1u described above. With the second coil patterns 79A1w and 79B1w and the second substrate 75B, the concentrated winding second substrate coil 57B1w (see, e.g., FIG. 16) is formed. The second coil patterns 79A2u and 79B2u are also configured in the same manner as the second coil patterns 77A1u and 77B1u described above. With the second coil patterns 79A2u and 79B2u and the second substrate 75B, the concentrated winding second substrate coil 57B2u (see, e.g., FIG. 16) is formed. The second coil patterns 79A2v and 79B2v are also configured in the same manner as the second coil patterns 77A1u and 77B1u described above. With the second coil patterns 79A2v and 79B2v and the second substrate 75B, the concentrated winding second substrate coil 57B2v (see, e.g., FIG. 16) is formed. The second coil patterns 79A2w and 79B2w are also configured in the same manner as the second coil patterns 77A1u and 77B1u described above. With the second coil patterns 79A2w and 79B2w and the second substrate 75B, the concentrated winding second substrate coil 57B2w (see, e.g., FIG. 16) is formed.

The end terminal EB2 of the second coil pattern 77B1u of the second substrate coil 57A and the start terminal EA1 of the second coil pattern 79A1u of the second substrate coil 57B are electrically connected by a connection line 81. Similarly, the end terminal EB2 of the second coil pattern 77B1v of the second substrate coil 57A and the start terminal EA1 of the second coil pattern 79A1v of the second substrate coil 57B are electrically connected by a connection line 81. Similarly, the end terminal EB2 of the second coil pattern 77B1w of the second substrate coil 57A and the start terminal EA1 of the second coil pattern 79A1w of the second substrate coil 57B are electrically connected by a connection line 81. Similarly, the end terminal EB2 of the second coil pattern 77B2u of the second substrate coil 57A and the start terminal EA1 of the second coil pattern 79A2u of the second substrate coil 57B are electrically connected by a connection line 81. Similarly, the end terminal EB2 of the second coil pattern 77B2v of the second substrate coil 57A and the start terminal EA1 of the second coil pattern 79A2v of the second substrate coil 57B are electrically connected by a connection line 81. Similarly, the end terminal EB2 of the second coil pattern 77B2w of the second substrate coil 57A and the start terminal EA1 of the second coil pattern 79A2w of the second substrate coil 57B are electrically connected by a connection line 81. The connection lines 81 may be provided within or outside the second substrate coils 57A and 57B in the XY-plane direction.

The second substrate coil 57C is configured such that substantially rectangular spiral-shaped second coil patterns 83A1u, 83A1v, 83A1w, 83A2u, 83A2v, and 83A2w each having its longitudinal direction following the Y-axis direction are formed on the front surface 75Ca of the second substrate 75C (e.g., the upper surface in the Z-axis direction; an example of a first surface), and second coil patterns 83B1u, 83B1v, 83B1w, 83B2u, 83B2v, and 83B2w are formed on the rear surface 75Cb of the second substrate 75C (e.g., the lower surface in the Z-axis direction; an example of a second surface). The second substrate 75C may be divided for each set including three U, V, and W phases, or may be divided for each of the U, V, and W phases. The Y-axis direction refers to the direction along the front surface 75Ca or the rear surface 75Cb of the second substrate 75C.

The second coil patterns 83A1u and 83B1u are also configured in the same manner as the second coil patterns 77A1u and 77B1u described above. With the second coil patterns 83A1u and 83B1u and the second substrate 75C, the concentrated winding second substrate coil 57C1u (see, e.g., FIG. 16) is formed. The second coil patterns 83A1v and 83B1v are also configured in the same manner as the second coil patterns 77A1u and 77B1u described above. With the second coil patterns 83A1v and 83B1v and the second substrate 75C, the concentrated winding second substrate coil 57C1v (see, e.g., FIG. 16) is formed. The second coil patterns 83A1w and 83B1w are also configured in the same manner as the second coil patterns 77A1u and 77B1u described above. With the second coil patterns 83A1w and 83B1w and the second substrate 75C, the concentrated winding second substrate coil 57C1w (see, e.g., FIG. 16) is formed. The second coil patterns 83A2u and 83B2u are also configured in the same manner as the second coil patterns 77A1u and 77B1u described above. With the second coil patterns 83A2u and 83B2u and the second substrate 75C, the concentrated winding second substrate coil 57C2u (see, e.g., FIG. 16) is formed. The second coil patterns 83A2v and 83B2v are also configured in the same manner as the second coil patterns 77A1u and 77B1u described above. With the second coil patterns 83A2v and 83B2v and the second substrate 75C, the concentrated winding second substrate coil 57C2v (see, e.g., FIG. 16) is formed. The second coil patterns 83A2w and 83B2w are also configured in the same manner as the second coil patterns 77A1u and 77B1u described above. With the second coil patterns 83A2w and 83B2w and the second substrate 75C, the concentrated winding second substrate coil 57C2w (see, e.g., FIG. 16) is formed.

The end terminal EB2 of the second coil pattern 79B1u of the second substrate coil 57B and the start terminal EA1 of the second coil pattern 83A1u of the second substrate coil 57C are electrically connected by a connection line 81. Similarly, the end terminal EB2 of the second coil pattern 79B1v of the second substrate coil 57B and the start terminal EA1 of the second coil pattern 83A1v of the second substrate coil 57C are electrically connected by a connection line 81. Similarly, the end terminal EB2 of the second coil pattern 79B1w of the second substrate coil 57B and the start terminal EA1 of the second coil pattern 83A1w of the second substrate coil 57C are electrically connected by a connection line 81. Similarly, the end terminal EB2 of the second coil pattern 79B2uof the second substrate coil 57B and the start terminal EA1 of the second coil pattern 83A2u of the second substrate coil 57C are electrically connected by a connection line 81. Similarly, the end terminal EB2 of the second coil pattern 79B2v of the second substrate coil 57B and the start terminal EA1 of the second coil pattern 83A2v of the second substrate coil 57C are electrically connected by a connection line 81. Similarly, the end terminal EB2 of the second coil pattern 79B2w of the second substrate coil 57B and the start terminal EA1 of the second coil pattern 83A2w of the second substrate coil 57C are electrically connected by a connection line 81. The connection lines 81 may be provided within or outside the second substrate coils 57B and 57C in the XY-plane direction.

The second substrate coil unit 49 includes second current inflow portions 83u1, 83v1, 83w1, 83u2, 83v2, and 83w2, through which current flows into the second substrate coils. The second current inflow portions 83u1, 83v1, 83w1, 83u2, 83v2, and 83w2 are arranged collectively at the end of the positive side in the Y-axis direction (e.g., an example of one side). For example, the second current inflow portion 83u1 is connected to the start terminal EA1 of the second coil pattern 77A1u, on the front surface 75Aa of the second substrate 75A. The second current inflow portion 83v1 is connected to the start terminal EA1 of the second coil pattern 77A1v, on the front surface 75Aa of the second substrate 75A. The second current inflow portion 83w1 is connected to the start terminal EA1 of the second coil pattern 77A1w, on the front surface 75Aa of the second substrate 75A. The second current inflow portion 83u2 is connected to the start terminal EA1 of the second coil pattern 77A2u, on the front surface 75Aa of the second substrate 75A. The second current inflow portion 83v2 is connected to the start terminal EA1 of the second coil pattern 77A2v, on the front surface 75Aa of the second substrate 75A. The second current inflow portion 83w2 is connected to the start terminal EA1 of the second coil pattern 77A2w, on the front surface 75Aa of the second substrate 75A.

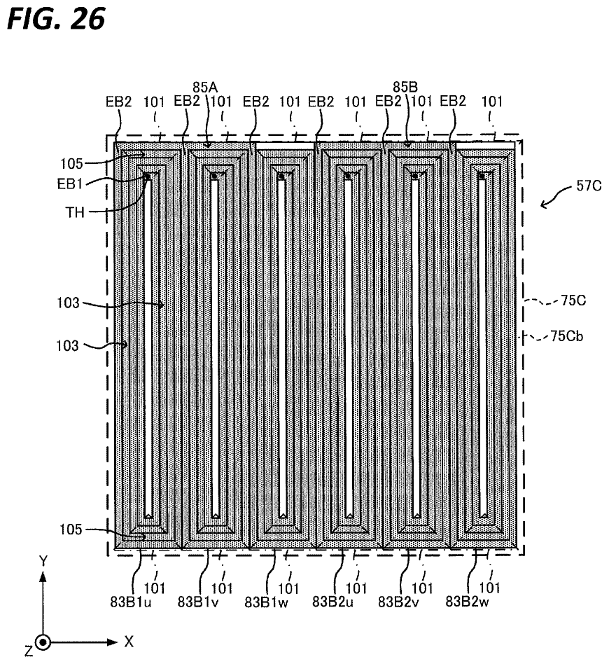

The second substrate coil unit 49 includes second neutral points 85A and 85B (see also, e.g., FIG. 26) to connect the plurality of second substrate coils having different phases (e.g., three U, V, and W phases). The second neutral points 85A and 85B are arranged collectively at the end of the positive side in the Y-axis direction (e.g., an example of one side). For example, the second neutral point 85A connects each of the end terminal EB2 of the second coil pattern 83B1u, the end terminal EB2 of the second coil pattern 83B1v, and the end terminal EB2 of the second coil pattern 83B1w, on the rear surface 75Cb of the second substrate 75C (see also, e.g., FIG. 26). The second neutral point 85B connects each of the end terminal EB2 of the second coil pattern 83B2u, the end terminal EB2 of the second coil pattern 83B2v, and the end terminal EB2 of the second coil pattern 83B2w, on the rear surface 75Cb of the second substrate 75C (see also, e.g., FIG. 26).

With the configuration above, the current flowing in from the second current inflow portion 83u1 passes through the second coil patterns 77A1u, 77B1u, 79A1u, 79B1u, 83A1u, and 83B1u and flows into the second neutral point 85A, the current flowing in from the second current inflow portion 83v1 passes through the second coil patterns 77A1v, 77B1v, 79A1v, 79B1v, 83A1v, and 83B1v and flows into the second neutral point 85A, and the current flowing in from the second current inflow portion 83w1 passes through the second coil patterns 77A1w, 77B1w, 79A1w, 79B1w, 83A1w, and 83B1w and flows into the second neutral point 85A, which forms a star connection (e.g., Y-connection). Similarly, the current flowing in from the second current inflow portion 83u2 passes through the second coil patterns 77A2u, 77B2u, 79A2u, 79B2u, 83A2u, and 83B2u and flows into the second neutral point 85B, the current flowing in from the second current inflow portion 83v2 passes through the second coil patterns 77A2v, 77B2v, 79A2v, 79B2v, 83A2v, and 83B2v and flows into the second neutral point 85B, and the current flowing in from the second current inflow portion 83w2 passes through the second coil patterns 77A2w, 77B2w, 79A2w, 79B2w, 83A2w, and 83B2w and flows into the second neutral point 85B, which forms a star connection (e.g., Y-connection).

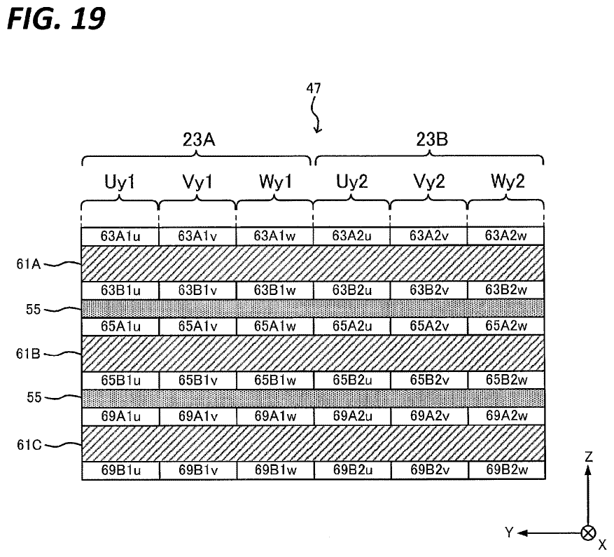

FIG. 19 conceptually illustrates an example of the layer configuration of the first substrate coil unit 47. The reference numeral for each first coil pattern in FIG. 19 corresponds to that in FIG. 17. As illustrated in FIG. 19, the first substrate coil unit 47 is formed by stacking, in the Z-axis direction, the first coil patterns 63A1u, 63A1v, 63A1w, 63A2u, 63A2v, and 63A2w, the first substrate 61A, the first coil patterns 63B1u, 63B1v, 63B1w, 63B2u, 63B2v, and 63B2w, the insulating layer 55, the first coil patterns 65A1u, 65A1v, 65A1w, 65A2u, 65A2v, and 65A2w, the first substrate 61B, the first coil patterns 65B1u, 65B1v, 65B1w, 65B2u, 65B2v, and 65B2w, the insulating layer 55, the first coil patterns 69A1u, 69A1v, 69A1w, 69A2u, 69A2v, and 69A2w, the first substrate 61C, and the first coil patterns 69B1u, 69B1v, 69B1w, 69B2u, 69B2v, and 69B2w.

The first coil patterns 63A1u, 63B1u, 65A1u, 65B1u, 69A1u, and 69B1u, the first substrates 61A, 61B, and 61C, and the insulating layers 55 correspond to the U-phase substrate coil Uy1 described above. The first coil patterns 63A1v, 63B1v, 65A1v, 65B1v, 69A1v, and 69B1v, the first substrates 61A, 61B, and 61C, and the insulating layers 55 correspond to the V-phase substrate coil Vy1 described above. The first coil patterns 63A1w, 63B1w, 65A1w, 65B1w, 69A1w, and 69B1w, the first substrates 61A, 61B, and 61C, and the insulating layers 55 correspond to the W-phase substrate coil Wy1 described above. The substrate coils Uy1, Vy1, and Wy1 make up the first substrate coil 23A described above.

Further, the first coil patterns 63A2u, 63B2u, 65A2u, 65B2u, 69A2u, and 69B2u, the first substrates 61A, 61B, and 61C, and the insulating layers 55 correspond to the U-phase substrate coil Uy2 described above. The first coil patterns 63A2v, 63B2v, 65A2v, 65B2v, 69A2v, and 69B2v, the first substrates 61A, 61B, and 61C, and the insulating layers 55 correspond to the V-phase substrate coil Vy2 described above. The first coil patterns 63A2w, 63B2w, 65A2w, 65B2w, 69A2w, and 69B2w, the first substrates 61A, 61B, and 61C, and the insulating layer 55 correspond to the W-phase substrate coil Wy2 described above. The substrate coils Uy2, Vy2, and Wy2 make up the first substrate coil 23B described above.

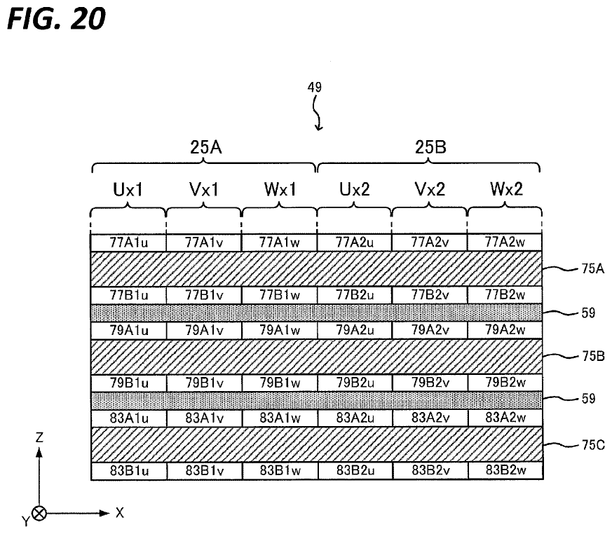

FIG. 20 conceptually illustrates an example of the layer configuration of the second substrate coil unit 49. The reference numeral for each second coil pattern in FIG. 20 corresponds to that in FIG. 18. As illustrated in FIG. 20, the second substrate coil unit 49 is formed by stacking, in the Z-axis direction, the second coil patterns 77A1u, 77A1v, 77A1w, 77A2u, 77A2v, and 77A2w, the second substrate 75A, the second coil patterns 77B1u, 77B1v, 77B1w, 77B2u, 77B2v, and 77B2w, the insulating layer 59, the second coil patterns 79A1u, 79A1v, 79A1w, 79A2u, 79A2v, and 79A2w, the second substrate 75B, the second coil patterns 79B1u, 79B1v, 79B1w, 79B2u, 79B2v, and 79B2w, the insulating layer 59, the second coil patterns 83A1u, 83A1v, 83A1w, 83A2u, 83A2v, and 83A2w, the second substrate 75C, and the second coil patterns 83B1u, 83B1v, 83B1w, 83B2u, 83B2v, and 83B2w.

The second coil patterns 77A1u, 77B1u, 79A1u, 79B1u, 83A1u, and 83B1u, the second substrates 75A, 75B, and 75C, and the insulating layer 59 correspond to the U-phase substrate coil Ux1 described above. The second coil patterns 77A1v, 77B1v, 79A1v, 79B1v, 83A1v, and 83B1v, the second substrates 75A, 75B, and 75C, and the insulating layer 59 correspond to the V-phase substrate coil Vx1 described above. The second coil patterns 77A1w, 77B1w, 79A1w, 79B1w, 83A1w, and 83B1w, the second substrates 75A, 75B, and 75C, and the insulating layer 59 correspond to the W-phase substrate coil Wx1 described above. The substrate coils Ux1, Vx1, and Wx1 make up the second substrate coil 25A described above.

Further, the second coil patterns 77A2u, 77B2u, 79A2u, 79B2u, 83A2u, and 83B2u, the second substrates 75A, 75B, and 75C, and the insulating layer 59 correspond to the U-phase substrate coil Ux2 described above. The second coil patterns 77A2v, 77B2v, 79A2v, 79B2v, 83A2v, and 83B2v, the second substrates 75A, 75B, and 75C, and the insulating layer 59 correspond to the V-phase substrate coil Vx2 described above. The second coil patterns 77A2w, 77B2w, 79A2w, 79B2w, 83A2w, and 83B2w, the second substrates 75A, 75B, and 75C, and the insulating layer 59 correspond to the W-phase substrate coil Wx1 described above. The substrate coils Ux2, Vx2, and Wx2 make up the second substrate coil 25B described above.

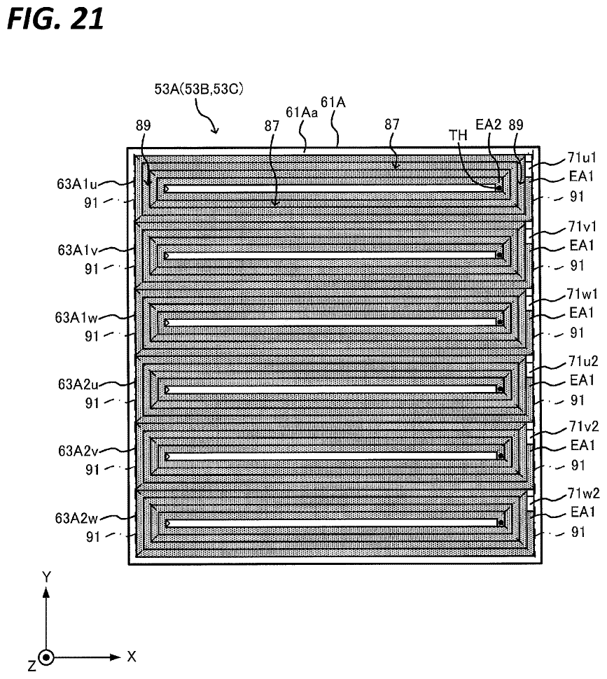

FIGS. 21 to 23 illustrate an example of the shape of the first coil patterns in the first substrate coil unit 47. FIG. 21 is a view of the first substrate coil 53A when viewed from above in the Z-axis direction. As illustrated in FIG. 21, the first coil patterns 63A1u, 63A1v, 63A1w, 63A2u, 63A2v, and 63A2w are formed on the front surface 61Aa of the first substrate 61A.

The first coil pattern 63A1u includes a plurality of first long coil pattern portions 87 extending in the X-axis direction, and a plurality of first short coil pattern portions 89 extending in the Y-axis direction. The first coil pattern 63A1u is formed in the substantially rectangular spiral shape by connecting the first long coil pattern portions 87 and the first short coil pattern portions 89 at a substantially right angle. Further, as described above, the first coil pattern 63A1u is formed in the substantially rectangular spiral shape having its longitudinal direction following the X-axis direction, such that the start terminal EA1 thereof in the current flow direction (e.g., an example of one terminal) is disposed near the edge of the first coil pattern 63A1u (e.g., the first substrate coil 53A1u), and the end terminal EA2 thereof (e.g., an example of the other terminal) is disposed near the center position of the first coil pattern 63A1u (e.g., the first substrate coil 53A1u) in the Y-axis direction. The first coil pattern 63A1u has the clockwise spiral shape with respect to the current flow direction as viewed from above in the Z-axis direction.

The first substrate coil 53A1u (see, e.g., FIG. 16) includes first coil end portions 91, which are regions where the first coil pattern 63A1u extends in the Y-axis direction, at both ends thereof in the X-axis direction. Each first coil end portion 91 is a substantially triangular region where the first short coil pattern portion 89 is disposed. The first current inflow portion 71u1 connected to the start terminal EA1 is disposed at the end of the positive side in the X-axis direction (e.g., an example of one side). The first current inflow portion 71u1 is disposed in the first coil end portion 91.

The first coil patterns 63A1v, 63A1w, 63A2u, 63A2v, and 63A2w are also formed in the same shape as the first coil pattern 63A1u.

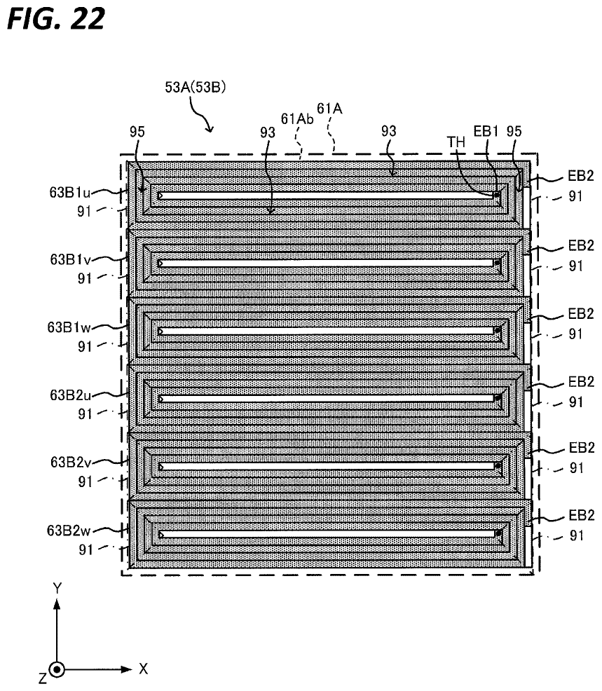

FIG. 22 is a view of the first substrate coil 53A as viewed from above in the Z-axis direction through the first substrate 61A. As illustrated in FIG. 22, the first coil patterns 63B1u, 63B1v, 63B1w, 63B2u, 63B2v, and 63B2w are formed on the rear surface 61Ab of the first substrate 61A.

The first coil pattern 63B1u includes a plurality of first long coil pattern portions 93 extending in the X-axis direction, and a plurality of first short coil pattern portions 95 extending in the Y-axis direction. The first coil pattern 63B1u is formed in the substantially rectangular spiral shape by connecting the first long coil pattern portions 93 and the first short coil pattern portions 95 at a substantially right angle. Further, as described above, the first coil pattern 63B1u is formed in the region overlapping with the first coil pattern 63A1u as viewed from the Z-axis direction. The first coil pattern 63B1u is formed in the substantially rectangular spiral shape having its longitudinal direction following the X-axis direction, such that the start terminal EB1 thereof in the current flow direction is disposed near the center position of the first coil pattern 63B1u (e.g., the first substrate coil 53A1u) in the Y-axis direction, and the end terminal EB2 thereof is disposed near the edge of the first coil pattern 63B1u (e.g., the first substrate coil 53A1u). The first coil pattern 63B1u has the clockwise spiral shape with respect to the current flow direction as viewed from above in the Z-axis direction. The first coil patterns 63A1u and 63B1u are formed such that their wiring patterns overlap with each other when viewed from the Z-axis direction. The end terminal EA2 of the first coil pattern 63A1u and the start terminal EB1 of the first coil pattern 63B1u are electrically connected via the through hole TH penetrating the first substrate 61A.

The first substrate coil 53A1u (see, e.g., FIG. 16) includes first coil end portions 91, which are regions where the first coil pattern 63B1u extends in the Y-axis direction, at both ends thereof in the X-axis direction. Each first coil end portion 91 is a substantially triangular region where the first short coil pattern portion 95 is disposed. The through hole TH is disposed in the first coil end portion 91.

The first coil patterns 63B1v, 63B1w, 63B2u, 63B2v, and 63B2w are also formed in the same shape as the first coil pattern 63B1u.

Although not illustrated, the configurations of FIGS. 21 and 22 identically apply to the front surface side and the rear surface side of the first substrate coil 53B and the front surface side of the first substrate coil 53C. However, the first current inflow portions are not provided in the first substrate coils 53B and 53C.

FIG. 23 is a view of the first substrate coil 53C as viewed from above in the Z-axis direction through the first substrate 61C. As illustrated in FIG. 23, the first coil patterns 69B1u, 69B1v, 69B1w, 69B2u, 69B2v, and 69B2w are formed on the rear surface 61Cb of the first substrate 61C.

The first coil patterns 69B1u, 69B1v, 69B1w, 69B2u, 69B2v, and 69B2w have the same configuration as the first coil patterns 63B1u, 63B1v, 63B1w, 63B2u, 63B2v, and 63B2w of FIG. 22, except that the first neutral points 73A and 73B are provided. As described above, the first neutral points 73A and 73B are disposed at the end of the positive side in the X-axis direction (e.g., an example of one side). The first neutral point 73A connects each of the end terminal EB2 of the first coil pattern 69B1u, the end terminal EB2 of the first coil pattern 69B1v, and the end terminal EB2 of the first coil pattern 69B1w. The first neutral point 73B connects each of the end terminal EB2 of the first coil pattern 69B2u, the end terminal EB2 of the first coil pattern 69B2v, and the end terminal EB2 of the first coil pattern 69B2w.

The first substrate coil 53C1u (see, e.g., FIG. 16) includes first coil end portions 91, which are regions where the first coil pattern 69B1u extends in the Y-axis direction, at both ends thereof in the X-axis direction. The first substrate coil 53C1v (see, e.g., FIG. 16) includes first coil end portions 91, which are regions where the first coil pattern 69B1v extends in the Y-axis direction, at both ends thereof in the X-axis direction. Each first coil end portion 91 is a substantially triangular region where the first short coil pattern portion 95 is disposed. The first neutral point 73A is disposed in the first coil end portions 91 of the first substrate coils 53C1u and 53C1v.

The first substrate coil 53C2u (see, e.g., FIG. 16) includes first coil end portions 91, which are regions where the first coil pattern 69B2u extends in the Y-axis direction, at both ends thereof in the X-axis direction. The first substrate coil 53C2v (see, e.g., FIG. 16) includes first coil end portions 91, which are regions where the first coil pattern 69B2v extends in the Y-axis direction, at both ends thereof in the X-axis direction. Each first coil end portion 91 is a substantially triangular region where the first short coil pattern portion 95 is disposed. The first neutral point 73B is disposed in the first coil end portions 91 of the first substrate coils 53C2u and 53C2v.

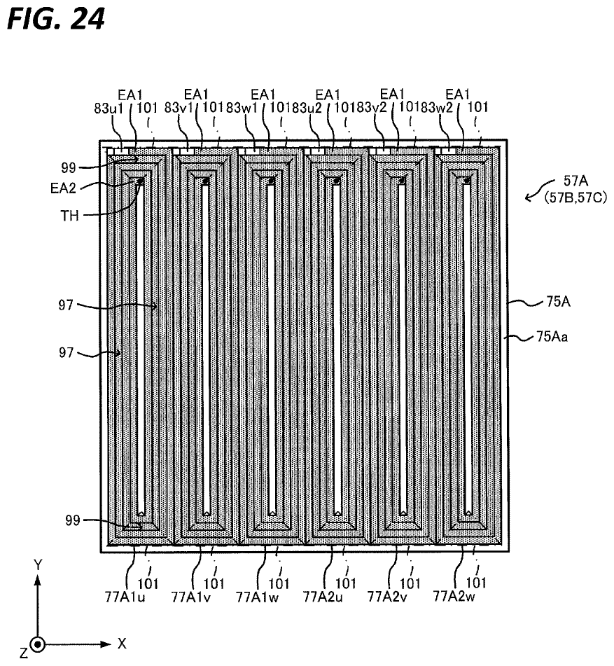

FIGS. 24 to 26 illustrate an example of the shape of the second coil patterns in the second substrate coil unit 49. FIG. 24 is a view of the second substrate coil 57A when viewed from above in the Z-axis direction. As illustrated in FIG. 24, the second coil patterns 77A1u, 77A1v, 77A1w, 77A2u, 77A2v, and 77A2w are formed on the front surface 75Aa of the second substrate 75A.

The second coil pattern 77A1u includes a plurality of second long coil pattern portions 97 extending in the Y-axis direction, and a plurality of second short coil pattern portions 99 extending in the X-axis direction. The second coil pattern 77A1u is formed in the substantially rectangular spiral shape by connecting the second long coil pattern portions 97 and the second short coil pattern portions 99 at a substantially right angle. Further, as described above, the second coil pattern 77A1u is formed in the substantially rectangular spiral shape having its longitudinal direction following the Y-axis direction, such that the start terminal EA1 thereof in the current flow direction (e.g., an example of one terminal) is disposed near the edge of the second coil pattern 77A1u (e.g., the second substrate coil 57A1u), and the end terminal EA2 thereof (e.g., an example of the other terminal) is disposed near the center position of the second coil pattern 77A1u (e.g., the second substrate coil 57A1u) in the X-axis direction. The second coil pattern 77A1u has the clockwise spiral shape with respect to the current flow direction as viewed from above in the Z-axis direction.

The second substrate coil 57A1u (see, e.g., FIG. 16) includes second coil end portions 101, which are regions where the second coil pattern 77A1u extends in the X-axis direction, at both ends thereof in the Y-axis direction. Each second coil end portion 101 is a substantially triangular region where the second short coil pattern portion 99 is disposed. The second current inflow portion 83u1 connected to the start terminal EA1 is disposed at the end of the positive side in the Y-axis direction (e.g., an example of one side). The second current inflow portion 83u1 is disposed in the second coil end portion 101.

The second coil patterns 77A1v, 77A1w, 77A2u, 77A2v, and 77A2w are also formed in the same shape as the second coil pattern 77A1u.

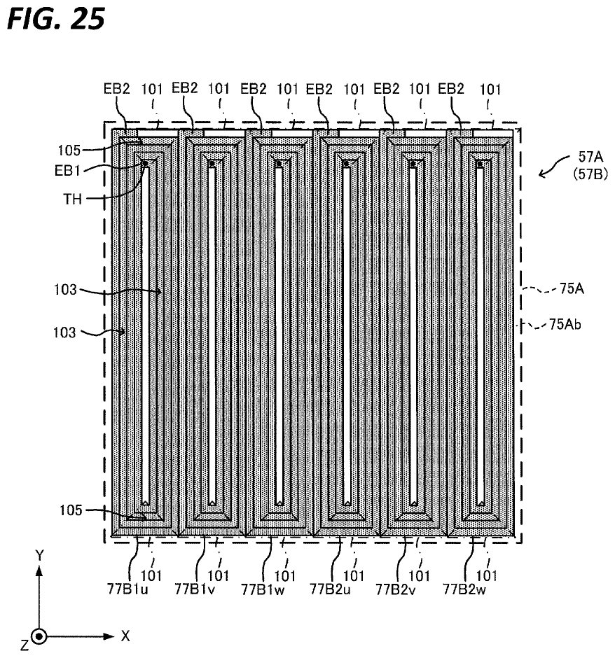

FIG. 25 is a view of the second substrate coil 57A as viewed from above in the Z-axis direction through the second substrate 75A. As illustrated in FIG. 25, the second coil patterns 77B1u, 77B1v, 77B1w, 77B2u, 77B2v, and 77B2w are formed on the rear surface 75Ab of the second substrate 75A.

The second coil pattern 77B1u includes a plurality of second long coil pattern portions 103 extending in the Y-axis direction, and a plurality of second short coil pattern portions 105 extending in the X-axis direction. The second coil pattern 77B1u is formed in the substantially rectangular spiral shape by connecting the second long coil pattern portions 103 and the second short coil pattern portions 105 at a substantially right angle. Further, as described above, the second coil pattern 77B1u is formed in the region overlapping with the second coil pattern 77A1u as viewed from the Z-axis direction. The second coil pattern 77B1u is formed in the substantially rectangular spiral shape having its longitudinal direction following the Y-axis direction, such that the start terminal EB1 thereof in the current flow direction is disposed near the center position of the second coil pattern 77B1u (e.g., the second substrate coil 57A1u) in the X-axis direction, and the end terminal EB2 thereof is disposed near the edge of the second coil pattern 77B1u (e.g., the second substrate coil 57A1u). The second coil pattern 77B1u has the clockwise spiral shape with respect to the current flow direction as viewed from above in the Z-axis direction. The second coil patterns 77A1u and 77B1u are formed such that their wiring patterns overlap with each other as viewed from the Z-axis direction. The end terminal EA2 of the second coil pattern 77A1u and the start terminal EB1 of the second coil pattern 77B1u are electrically connected via the through hole TH penetrating the second substrate 75A.

The second substrate coil 57A1u (see, e.g., FIG. 16) includes second coil end portions 101, which are regions where the second coil pattern 77B1u extends in the X-axis direction, at both ends thereof in the Y-axis direction. Each second coil end portion 101 is a substantially triangular region where the second short coil pattern portion 105 is disposed. The through hole TH is disposed in the second coil end portion 101.

The second coil patterns 77B1v, 77B1w, 77B2u, 77B2v, and 77B2w are also formed in the same shape as the second coil pattern 77B1u.

Although not illustrated, the configurations of FIGS. 24 and 25 identically apply to the front surface side and the rear surface side of the second substrate coil 57B and the front surface side of the second substrate coil 57C. However, the second current inflow portions are not provided in the second substrate coils 57B and 57C.

FIG. 26 is a view of the second substrate coil 57C as viewed from above in the Z-axis direction through the second substrate 75C. As illustrated in FIG. 26, the second coil patterns 83B1u, 83B1v, 83B1w, 83B2u, 83B2v, and 83B2w are formed on the rear surface 75Cb of the second substrate 75C.

The second coil patterns 83B1u, 83B1v, 83B1w, 83B2u, 83B2v, and 83B2w have the same configuration as the second coil patterns 77B1u, 77B1v, 77B1w, 77B2u, 77B2v, and 77B2w of FIG. 25, except that the second neutral points 85A and 85B are provided. As described above, the second neutral points 85A and 85B are disposed at the end of the positive side in the Y-axis direction (e.g., an example of one side). The second neutral point 85A connects each of the end terminal EB2 of the second coil pattern 83B1u, the end terminal EB2 of the second coil pattern 83B1v, and the end terminal EB2 of the second coil pattern 83B1w. The second neutral point 85B connects each of the end terminal EB2 of the second coil pattern 83B2u, the end terminal EB2 of the second coil pattern 83B2v, and the end terminal EB2 of the second coil pattern 83B2w.

The second substrate coil 57C1u (see, e.g., FIG. 16) includes second coil end portions 101, which are regions where the second coil pattern 83B1u extends in the X-axis direction, at both ends thereof in the Y-axis direction. The second substrate coil 57C1v (see, e.g., FIG. 16) includes second coil end portions 101, which are regions where the second coil pattern 83B1v extends in the X-axis direction, at both ends thereof in the Y-axis direction. Each second coil end portion 101 is a substantially triangular region where the second short coil pattern portion 105 is disposed. The second neutral point 85A is disposed in the second coil end portions 101 of the second substrate coils 57C1u and 57C1v.

The second substrate coil 57C2u (see, e.g., FIG. 16) includes second coil end portions 101, which are regions where the second coil pattern 83B2u extends in the X-axis direction, at both ends thereof in the Y-axis direction. The second substrate coil 57C2v (see, e.g., FIG. 16) includes second coil end portions 101, which are regions where the second coil pattern 83B2v extends in the X-axis direction, at both ends thereof in the Y-axis direction. Each second coil end portion 101 is a substantially triangular region where the second short coil pattern portion 105 is disposed. The second neutral point 85B is disposed in the second coil end portions 101 of the second substrate coils 57C2u and 57C2v.

### 5. Configuration of Servo Amplifier

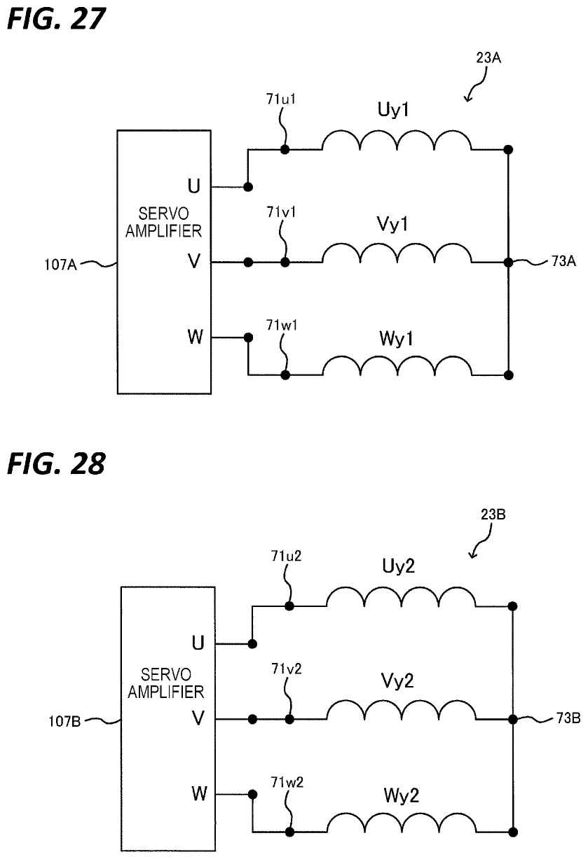

Next, an example of the configuration of a servo amplifier that supplies current to the stator 11 will be described with reference to FIGS. 27 to 30.

As described above, the stator 11 includes the two sets of first substrate coils 23A and 23B, and the two sets of second substrate coils 25A and 25B (see, e.g., FIG. 2). The four substrate coils 23A, 23B, 25A, and 25B are not electrically connected to each other, and are configured as independent electrical circuits. For one stator 11, the controller 15 controls the current supplied to the four substrate coils 23A, 23B, 25A, and 25B independently on a per-substrate-coil basis through four servo amplifiers 107A, 107B, 107C, and 107D, respectively. The four servo amplifiers 107A, 107B, 107C, and 107D may be unitized by being inserted into the stator unit 21.

As illustrated in FIG. 27, the first substrate coil 23A is configured with the substrate coils Uy1, Vy1, and Wy1. The current inflow portion 71u1 of the substrate coil Uy1, the current inflow portion 71v1 of the substrate coil Vy1, and the current inflow portion 71w1 of the substrate coil Wy1 are connected to the servo amplifier 107A. The ends of the substrate coils Uy1, Vy1, and Wy1 opposite to the servo amplifier 107A are connected to the neutral point 73A, forming the star connection (e.g., Y-connection).

As illustrated in FIG. 28, the first substrate coil 23B is configured with the substrate coils Uy2, Vy2, and Wy2. The current inflow portion 71u2 of the substrate coil Uy2, the current inflow portion 71v2 of the substrate coil Vy2, and the current inflow portion 71w2 of the substrate coil Wy2 are connected to the servo amplifier 107B. The ends of the substrate coils Uy2, Vy2, and Wy2 opposite to the servo amplifier 107B are connected to the neutral point 73B, forming the star connection (e.g., Y-connection).

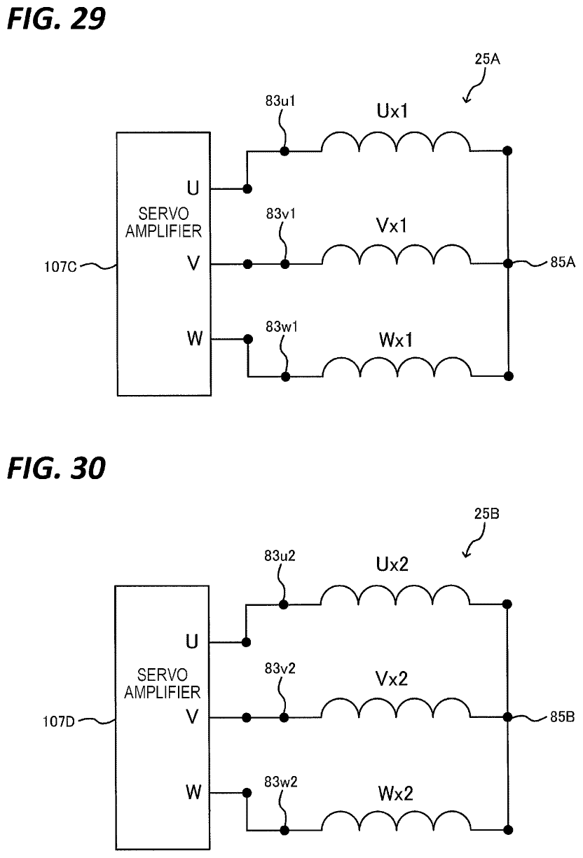

As illustrated in FIG. 29, the second substrate coil 25A is configured with the substrate coils Ux1, Vx1, and Wx1. The current inflow portion 83u1 of the substrate coil Ux1, the current inflow portion 83v1 of the substrate coil Vx1, and the current inflow portion 83w1 of the substrate coil Wx1 are connected to the servo amplifier 107C. The ends of the substrate coils Ux1, Vx1, and Wx1 opposite to the servo amplifier 107C are connected to the neutral point 85A, forming the star connection (e.g., Y-connection).

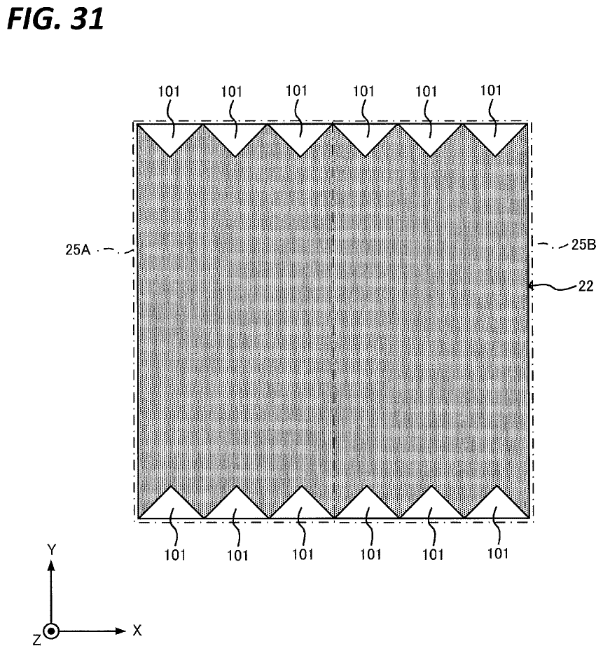

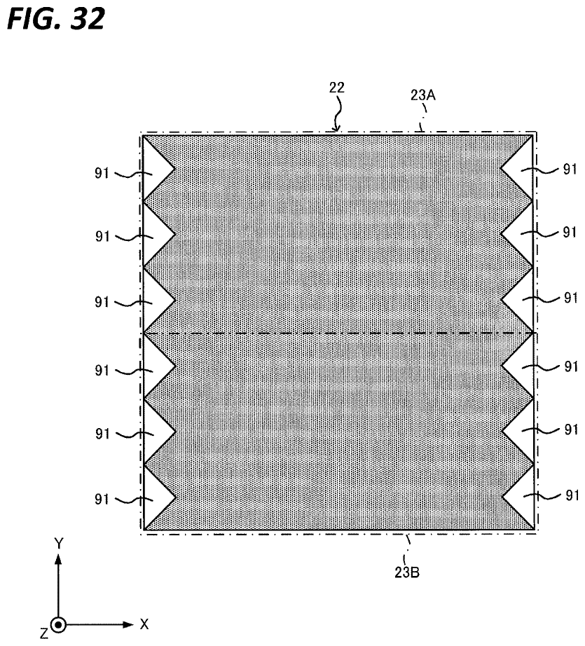

As illustrated in FIG. 30, the second substrate coil 25B is configured with the substrate coils Ux2, Vx2, and Wx2. The current inflow portion 83u2 of the substrate coil Ux2, the current inflow portion 83v2 of the substrate coil Vx2, and the current inflow portion 83w2 of the substrate coil Wx2 are connected to the servo amplifier 107D. The ends of the substrate coils Ux2, Vx2, and Wx2 opposite to the servo amplifier 107D are connected to the neutral point 85B, forming the star connection (e.g., Y-connection).

The connection of the substrate coils is not limited to the star connection (e.g., Y-connection), and may be, for example, a delta connection.

### 6. Relationship between Coil Unit of Stator and Magnet Unit of Mover

Next, an example of the relationship in size between the coil unit 22 of the stator 11 and the magnet unit 27 of the mover 13 will be described with reference to FIGS. 31 to 34.

FIG. 31 illustrates the region where the propulsion force in the X-axis direction is obtained, in the coil unit 22 of the stator 11. As illustrated in FIG. 31, among the substrate coils included in the coil unit 22, the second substrate coils 25A and 25B impart the propulsion force in the X-axis direction to the mover 13. In the second substrate coils 25A and 25B, the second coil end portions 101 are the regions where the second coil patterns extend in the X-axis direction (e.g., white portions in FIG. 31), and do not contribute to the propulsion force in the X-axis direction. Thus, the region of the coil unit 22 other than the second coil end portions 101 (e.g., gray portion in FIG. 31) is the region where the propulsion force in the X-axis direction is obtained.

FIG. 32 illustrates the region where the propulsion force in the Y-axis direction is obtained, in the coil unit 22 of the stator 11. As illustrated in FIG. 32, among the substrate coils included in the coil unit 22, the first substrate coils 23A and 23B impart the propulsion force in the Y-axis direction to the mover 13. In the first substrate coils 23A and 23B, the first coil end portions 91 are the regions where the first coil patterns extend in the Y-axis direction (e.g., white portions in FIG. 32), and do not contribute to the propulsion force in the Y-axis direction. Thus, the region of the coil unit 22 other than the first coil end portions 91 (e.g., gray portion in FIG. 32) is the region where the propulsion in the Y-axis direction is obtained.

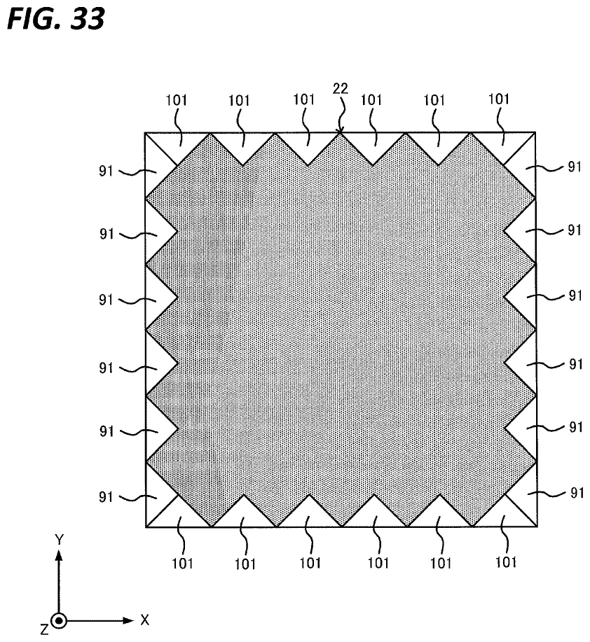

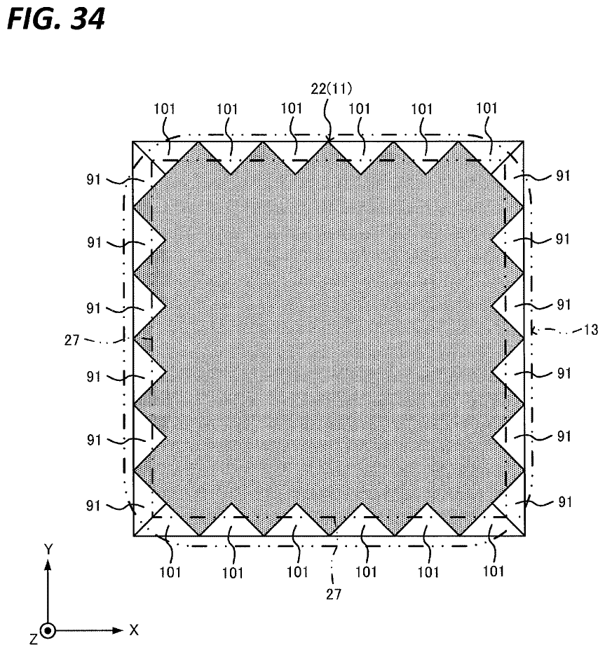

FIG. 33 illustrates the region where the levitation force in the Z-axis direction is reliably obtained, in the coil unit 22 of the stator 11. As illustrated in FIG. 33, when viewed from the Z-axis direction, the coil unit 22 includes the coil end portions 91 and 101 (e.g., white portions in FIG. 33) that include both the first coil end portions 91, which are the regions where the first coil patterns of the first substrate coils 23A and 23B extend in the Y-axis direction, and the second coil end portions 101, which are the regions where the second coil patterns of the second substrate coils 25A and 25B extend in the X-axis direction. Since the region other than the coil end portions 91 and 101 (e.g., gray portion in FIG. 33) is the region where the propulsion force in both the X-axis direction and the Y-axis direction is obtained, a high levitation force is obtained. Meanwhile, since the regions of the coil end portions 91 and 101 are the regions where the propulsion force in only either one of the X-axis direction and the Y-axis direction is obtained, decrease of the propulsion force and the levitation force occurs.

FIG. 34 illustrates an example of the relationship in size between the coil unit 22 of the stator 11 and the magnet unit 27 of the mover 13. As illustrated in FIG. 34, the mover 13 is configured such that at the position facing the stator 11, when viewed from the Z-axis direction, the outer periphery of the installation range of the magnet unit 27 overlaps with both the regions of the coil end portions 91 on one side and the other side in the X-axis direction, respectively, and also overlaps with both the regions of the coil end portions 101 on one side and the other side in the Y-axis direction, respectively. Further, the mover 13 is configured such that the dimensions of the outer periphery of the installation range of the magnet unit 27 in the X-axis direction and the Y-axis direction are equal to or smaller than the dimensions of the coil unit 22 of the stator 11 in the X-axis direction and Y-axis direction, respectively. In other words, the mover 13 is configured such that the size of the outer periphery of the installation range of the magnet unit 27 is larger than the quadrilateral region defined by connecting the inner vertices of the coil end portions 91 and 101, and equal to or smaller than the size of the quadrilateral outer periphery of the coil unit 22.

The mover 13 may be configured such that the outer periphery of the installation range of the magnet unit 27 overlaps with both the regions of the coil end portions 91 on one side and the other side in the X-axis direction, respectively, but does not overlap with both the regions of the coil end portions 101 on one side and the other side in the Y-axis direction. Further, the mover 13 may be configured such that the outer periphery of the installation range of the magnet unit 27 overlaps with both the regions of the coil end portions 101 on one side and the other side in the Y-axis direction, respectively, but does not overlap with both the regions of the coil end portions 91 on one side and the other side in the X-axis direction.

The mover 13 moves along at least one of the X-axis direction and the Y-axis direction, while crossing the coil end portions 91 and 101 of the plurality of stators 11 arranged in a row. In this case, by meeting the relationship in size between the coil unit 22 of the stator 11 and the magnet unit 27 of the mover 13 as described above, adverse effects (e.g., cogging and ripple) caused from the decrease in propulsion force and levitation force due to the coil end portions 91 and 101 may be suppressed, so that the stability of the operation of the mover 13 may be improved.

### 7. Effects of Embodiment

As described above, in the substrate transfer system 1 of the present embodiment, the plurality of stators 11 are arranged in a row along the X-axis direction to form the first transfer path 19A. The mover 13 levitates and moves on the first transfer path 19A, to transfer the semiconductor substrate W. According to the present embodiment, since the trajectory or control of the mover 13 may be simplified, the substrate transfer system 1 may be downsized, and the expandability may be improved.

In the present embodiment, the two first transfer paths 19A may be arranged apart from each other in the Y-axis direction. In this case, even when a mover 13 stops due to a failure or the like in one of the first transfer paths 19A, another mover 13 may be operated on the other first transfer path 19A. As a result, the downtime of the substrate transfer system 1 may be reduced.

In the present embodiment, the second transfer path 19B may be formed to connect the two first transfer paths 19A in the Y-axis direction. In this case, the transfer path may be formed in a ladder shape. As a result, while enabling the planar movement of the mover 13, the configuration and control may be simplified, as compared to free trajectory. Further, in a case where a plurality of movers 13 is arranged, even when any one of the movers 13 stops due to a failure or the like, another mover 13 may perform, for example, overtaking, passing each other, and detouring, so that the operation of the system may be continued. Therefore, the downtime of the system may be further reduced.

In the present embodiment, the second transfer path 19B may connect the two first transfer paths 19A at a position between two adjacent processing chambers 9 in the X-axis direction. In this case, even when a mover 13 stops due to a failure or the like in front of a processing chamber 9, another mover 13 may perform, for example, overtaking, passing each other, and detouring, so that the operation of the system may be continued. Further, the transfer path 19 may be formed in the ladder shape, using the stator units 21 having the same arrangement pattern of the stators 11.

In the present embodiment, the third transfer path 19C may be formed to connect the first transfer path 19A and a processing chamber 9 in the Y-axis direction. In this case, the mover 13 may be moved in directions close to and away from a processing chamber 9, through the third transfer path 19C. As a result, the position of the mover 13 may be adjusted when the semiconductor substrate W is loaded/unloaded into/from a processing chamber 9.

In the present embodiment, the plurality of stators 11 may be arranged on the upper surface of the base 32 to be unitized as the stator unit 21, and the transfer path 19 may be formed by connecting the plurality of stator units 21. In this case, the transfer path 19 may easily be expanded or modified by, for example, adding or modifying the stator units 21. Therefore, a flexible system may be implemented.

In the present embodiment, the plurality of stators 11 may be arranged adjacent to each other on the upper surface of the base 32 of the stator unit 21. In this case, a transfer path corresponding to the arrangement of the stators 11 may be formed on the upper surface of the base 32.

In the present embodiment, the upper surface of the base 32 may be divided into nine regions by being equally divided into three regions in both the longitudinal direction and the transverse direction, and the plurality of stators 11 may be arranged in predetermined regions among the nine regions. In this case, the following effects are achieved. That is, when the upper surface of the base 32 is divided into four regions (2×2), the number of transfer path patterns that may be formed is overly small, and when the upper surface of the base 32 is divided into 16 regions (4×4), the number of transfer path patterns that may be formed increases, but the unit configuration becomes complicated. According to the present embodiment, by dividing the upper surface of the base 32 into nine regions (3×3), both the simplification of the unit configuration and the appropriate number of transfer path patterns may be achieved. As a result, for example, the expansion or modification of the transfer path 19 may be facilitated.

In the present embodiment, the stator unit 21 may be configured such that, when viewed from the Z-axis direction, the stators 11 are arranged in contact with the edges of at least two sides of the four sides of the base 32. In this case, for example, the stator unit 21 may be formed to correspond to various transfer path patterns such as a linear shape, L-shape, T-shape, and cross shape.

In the present embodiment, the dimensions of the mover 13 in the X-axis direction and the Y-axis direction may be substantially the same as those of the stator 11. In this case, since the mover 13 has substantially the same dimension as the stator 11, the design of the transfer path 19 may be facilitated.

In the present embodiment, when two movers 13 move in the direction approaching each other on one first transfer path 19A, the controller 15 may control one of the two movers 13 to move to the other first transfer path 19A via the second transfer path 19B, so that the two movers 13 pass each other. In this case, in the ladder-shaped transfer path 19, the two movers 13 may be operated to pass each other.

Further, in the present embodiment, when two movers 13 move in the same direction on one first transfer path 19A, the controller 15 may control the mover 13 on the rear side in the moving direction to move to the other first transfer path 19A via the second transfer path 19B, thereby overtaking the mover 13 on the front side in the moving direction. In this case, in the ladder-shaped transfer path 19, the mover 13 on the rear side may be operated to overtake the mover 13 on the front side.

In the present embodiment, when another mover 13 is present in front of a mover 13 moving on one first transfer path 19A, the controller 15 may control the moving mover 13 to move to the other transfer path 19A via the second transfer path 19B, thereby bypassing the another mover 13. In this case, in the ladder-shaped transfer path 19, the moving mover 13 may be operated to bypass the mover 13 stopped in front of the moving mover 13.

In the present embodiment, when a mover 13 is moved toward a specific processing chamber 9 connected to one first transfer path 19A, the controller 15 may control the mover 13 to approach the specific processing chamber 9 from one side in the X-axis direction, and furthermore, may control the mover 13 to detour via the other first transfer path 19A, thereby approaching the specific processing chamber 9 from the other side in the X-axis direction. In this case, since options for transfer routes when the mover 13 is moved to a specific destination (e.g., the specific processing chamber 9) increase, the degree of freedom in transfer routes may be improved.

In the present embodiment, the controller 15 may control the position of the mover 13 such that two or more movers 13 are not positioned on a single stator 11. In this case, the collision between the movers 13 may be avoided.

In the present embodiment, the controller 15 may control the position of the mover 13 such that two or more movers 13 are not positioned on a single base 32. In this case, the approach between the movers 13 may be avoided.

In the present embodiment, the stators 11 on the upper surface of the stator unit 21 may be covered with the covering member 34. In this case, the following effects may be achieved. That is, the coils of the stators 11 are molded using the resin 33, but moisture is released from the resin 33 in the vacuum environment, which causes an increase in pressure. Further, when the vacuum transfer chamber 7 is maintained under the vacuum environment, a corrosive gas may enter from the processing chamber 9, and corrode the stators 11 and the resin 33. According to the present embodiment, by covering the stators 11 on the upper surface of the stator unit 21 with the covering member 34, the stators 11 and the resin 33 may be sealed, so that the concerns described above may be avoided. Therefore, a system capable of withstanding the vacuum environment may be implemented.

In the present embodiment, the stator unit 21 may include one or more sensors 36 and 38 between the base 32 and the stator 11, to detect the position of the mover 13. In this case, the position of the mover 13 may be precisely controlled.

In the present embodiment, the stator unit 21 may be configured such that the number of sensors of the stator 11 connected to a processing chamber 9 (e.g., the number of sensors 36 and 38) is greater than the number of sensors of the stator 11 that is not connected to a processing chamber 9 (e.g., the number of sensors 36). In this case, the positioning accuracy of the mover 13 when the semiconductor substrate W is loaded/unloaded into/from the processing chamber 9 may be improved, as compared to the positioning accuracy when the semiconductor substrate W is transferred.

In the present embodiment, the number of sensors in the stator unit 21 connected to a processing chamber 9 (e.g., the number of sensors 36 and 38) may be greater than the number of sensors in the stator unit 21 that is not connected to a processing chamber 9 (e.g., the number of sensors 36). In this case, the positioning accuracy of the mover 13 when the mover 13 is located near the processing chamber 9 may be improved, as compared to the positioning accuracy when the mover 13 is located away from the processing chamber 9.

In the present embodiment, the stator unit 21 may include the heat transfer member 39 disposed between the base 32 and the stator 11 to transfer heat generated in the stator 11 to the base 32. In this case, since the heat generated in the stator 11 may be efficiently transferred and dispersed to the base 32 by the heat transfer member 39, so that the heat dissipation performance may be improved.

As described above, the stator 11 of the planar motor 20 included in the substrate transfer system 1 of the present embodiment includes the plurality of concentrated winding first substrate coils 53A, 53B, and 53C, in which the substantially rectangular spiral-shaped first coil patterns each having its longitudinal direction following the X-axis direction are formed on the first substrates 61A, 61B, and 61C. By forming coil patterns on a substrate to obtain substrate coils, coils with a large area and a high flatness may be implemented, as compared to wound coils. As a result, the cause for cogging or ripple may be reduced. Further, as compared to wound coils, the number of windings may be increased while suppressing an increase in volume, and furthermore, an increase in size of the coil end portions may be suppressed so that the stator 11 may be downsized (e.g., thinned). Further, by forming the substrate coils in the concentrated winding manner, a planar turn configuration on the surface of the substrate may be achieved, which may facilitate the manufacturing as compared to distributed winding with a three-dimensional turn configuration. Further, since the number of windings may be easily increased as compared to the distributed winding, the range of propulsion force that may be output may be expanded, and the versatility may be improved.

In the present embodiment, the stator 11 of the planar motor 20 may include the plurality of concentrated winding second substrate coils 57A, 57B, and 57C, in which the substantially rectangular spiral-shaped second coil patterns each having its longitudinal direction following the Y-axis direction are formed on the second substrates 75A, 75B, and 75C, and may be configured such that the first substrate coils 53A, 53B, and 53C and the second substrate coils 57A, 57B, and 57C are stacked in the Z-axis direction. In this case, the mover 13 may be controlled with three degrees of freedom including movements in the horizontal direction (each direction in the plane including the X-axis direction and the Y-axis direction) and a movement in the rotation direction around the axis of the Z-axis direction. The mover 13 may also be controlled with six degrees of freedom further including a vertical movement in the Z-axis direction, a movement in the rotation direction around the axis of the X-axis direction, and a movement in the rotation direction around the axis of the Y-axis direction.

In the present embodiment, the first substrates 61A, 61B, and 61C, on which the first coil patterns are formed, and the second substrates 75A, 75B, and 75C, on which the second coil patterns are formed, may be provided as separate substrates. In this case, the manufacturing of the substrate coils may be facilitated.

In the present embodiment, each of the first substrate coils 53A, 53B, and 53C and the second substrate coils 57A, 57B, and 57C may be configured such that coil patterns are formed on both surfaces of each substrate and connected via through holes TH. In this case, the number of windings of the coils may be further increased while suppressing an increase in volume.

In the present embodiment, when viewed from the Z-axis direction, the external shape of the installation region of the magnet unit 27 of the mover 13 may be configured to overlap with the coil end portions 91 and 101 of one stator 11 in at least one of the X-axis direction and the Y-axis direction. In this case, as compared to a case where the external shape of the installation region of the magnet unit 27 of the mover 13 is smaller than the coil end portions 91 and 101, adverse effects (e.g., cogging and ripple) caused from the decrease in propulsion force and levitation force due to the coil end portions 91 and 101 of the stator 11 may be suppressed, so that the stability of the mover 13 during its operation may be improved.

In the present embodiment, the dimensions of the installation range of the magnet unit 27 of the mover 13 in the X-axis direction and the Y-axis direction may be configured to be equal to or smaller than the dimensions of the coil unit 22 of the stator 11 in the X-axis direction and the Y-axis direction, respectively. In this case, the mover 13 and the stator 11 may be configured to have substantially the same dimension, so that the design and manufacturing of the planar motor 20 or the transfer path 19 are facilitated.

In the present embodiment, the first coil patterns may include the plurality of first long coil pattern portions 87 extending in the X-axis direction and the plurality of first short coil pattern portions 89 extending in the Y-axis direction, and may be formed in the substantially rectangular spiral shape by connecting the first long coil pattern portions 87 and the first short coil pattern portions 89 at a substantially right angle. Further, the second coil patterns may include the plurality of second long coil pattern portions 97 extending in the Y-axis direction and the plurality of second short coil pattern portions 99 extending in the X-axis direction, and may be formed in the substantially rectangular spiral shape by connecting the second long coil pattern portions 97 and the second short coil pattern portions 99 at a substantially right angle. In this case, as compared to wound coils in which coil end portions are bent in an arc shape, the coil end portions that do not contribute to the propulsion force may be reduced. As a result, the region of the substrate coils that contributes to the propulsion force may be expanded to the vicinity of the outer periphery, so that the operation efficiency (e.g., stability of propulsion force) of the planar motor 20 may be improved.

In the present embodiment, the first coil pattern may be formed in the spiral shape such that one end thereof is disposed near the edge of the first substrate coil, and the other end thereof is disposed near the center position of the first substrate coil in the Y-axis direction. Further, the second coil pattern may be formed in the spiral shape such that one end thereof is disposed near the edge of the second substrate coil, and the other end thereof is disposed near the center position of the second substrate coil in the X-axis direction. In this case, as compared to wound coils, the air-core part (e.g., the central region where no coil pattern is formed) may be reduced, so that the space factor of coils (e.g., the ratio of conductor occupied in the cross section of coils) may be improved.

In the present embodiment, the current inflow portions for introducing current into the respective substrate coils may be arranged collectively at one end of each substrate coil in its longitudinal direction. In this case, the routing of the wiring connected to each substrate coil may be facilitated.

In the present embodiment, the first current inflow portions may be disposed in the first coil end portions 91. Further, the second current inflow portions may be disposed in the second coil end portions 101. In this case, since the current inflow portions may be provided within the substrate, the stator 11 may be downsized as compared to a case where the current inflow portions are provided outside the substrate. Further, since the current inflow portions are disposed in the coil end portions 91 and 101 that do not contribute to the propulsion force, the influence on the propulsion force may be reduced.

In the present embodiment, the neutral points 73A, 73B, 85A, and 85B, which connect the plurality of substrate coils having different phases, may be arranged collectively at one end of each substrate coil in its longitudinal direction. In this case, as compared to a case where the neutral points 73A, 73B, 85A, and 85B are arranged at a middle position of each substrate coil in its longitudinal direction, a reduction in the number of coil windings may be suppressed.

In the present embodiment, the first neutral points 73A and 73B may be disposed in the first coil end portions 91. Further, the second neutral points 85A and 85B may be disposed in the second coil end portions 101. In this case, since the neutral points 73A, 73B, 85A, and 85B may be provided within the substrate, the stator 11 may be downsized, as compared to a case where the neutral points 73A, 73B, 85A, and 85B are provided outside the substrate. Further, since the neutral points 73A, 73B, 85A, and 85B are disposed in the coil end portions 91 and 101 that do not contribute to the propulsion force, the influence on the propulsion force may be reduced.

In the substrate transfer system 1 of the present embodiment, the stator 11 includes the plurality of concentrated winding second substrate coils 57A, 57B, and 57C, in which the substantially rectangular spiral-shaped second coil patterns each having its longitudinal direction following the Y-axis direction are formed. Further, the first transfer path 19A is formed by arranging the plurality of stators 11 in a row along the X-axis direction. The mover 13 levitates on the first transfer path 19A and moves in the X-axis direction, by the propulsion force generated in the X-axis direction between the mover 13 and the second substrate coils 57A, 57B, and 57C, thereby transferring the semiconductor substrate W. According to the present embodiment, since the trajectory or control of the mover 13 may be simplified, the substrate transfer system 1 may be downsized, and the expandability may be improved. Further, by forming the substrate coils in the concentrated winding manner, a planar turn configuration on the surface of the substrate may be achieved, which may facilitate the manufacturing as compared to distributed winding with a three-dimensional turn configuration. Further, since the number of windings may be easily increased as compared to distributed winding, the range of propulsion force that may be output may be expanded, and the versatility may be improved.

In the substrate transfer system 1 according to the present embodiment, the stator 11 includes the first substrate coils 53A, 53B, and 53C and the second substrate coils 57A, 57B, and 57C. Further, the plurality of stators 11 are arranged in a row along the X-axis direction to form the first transfer path 19A, and at least one stator 11 is arranged in a row along the Y-axis direction to form the second transfer path 19B connecting two first transfer paths 19A. The mover 13 levitates on the first transfer path 19A and the second transfer path 19B and moves in the X-axis direction and the Y-axis direction, by the propulsion force generated in the X-axis direction and the Y-axis direction between the mover 13 and the first substrate coils 53A, 53B, and 53C/the second substrate coils 57A, 57B, and 57C, thereby transferring the semiconductor substrate W. According to the present embodiment, since the trajectory or control of the mover 13 may be simplified, the substrate transfer system 1 may be downsized, and the expandability may be improved. Further, by forming the substrate coils in the concentrated winding manner, a planar turn configuration on the surface of the substrate may be achieved, which may facilitate the manufacturing as compared to distributed winding with a three-dimensional turn configuration. Further, since the number of windings may be easily increased as compared to distributed winding, the range of propulsion force that may be output may be expanded, and the versatility may be improved. Further, the stator 11 is configured by stacking the first substrate coils 53A, 53B, and 53C and the second substrate coils 57A, 57B, and 57C, so that the mover 13 may be controlled with three degrees of freedom including the movements in the horizontal direction (e.g., each direction in the plane including the X-axis direction and the Y-axis direction) and the movement in the rotation direction around the axis of the Z-axis direction. Further, the mover 13 may be controlled with six degrees of freedom further including the vertical movement in the Z-axis direction, the movement in the rotation direction around the axis of the X-axis direction, and the movement in the rotation direction around the axis of the Y-axis direction. Therefore, the levitation force and the propulsion force are further stabilized, and degrees of freedom in the propulsion direction increase.

In the present embodiment, the mover 13 may move along at least one of the X-axis direction and the Y-axis direction while crossing the coil end portions 91 and 101 of the plurality of stators 11 arranged in a row. In this case, adverse effects (e.g., cogging and ripple) caused from the decrease in propulsion force due to the coil end portions 91 and 101 of the stators 11 may be suppressed, so that the stability of the operation of the mover 13 may be improved when the mover 13 moves.

### 8. Modifications

The embodiment of the present disclosure is not limited to that described above, and various modifications may be made within the scope that does not depart from the gist and technical idea of the present disclosure. Hereinafter, the modifications will be described.

### (8-1. When Second Transfer Path is Formed at Position Facing Processing Chamber)

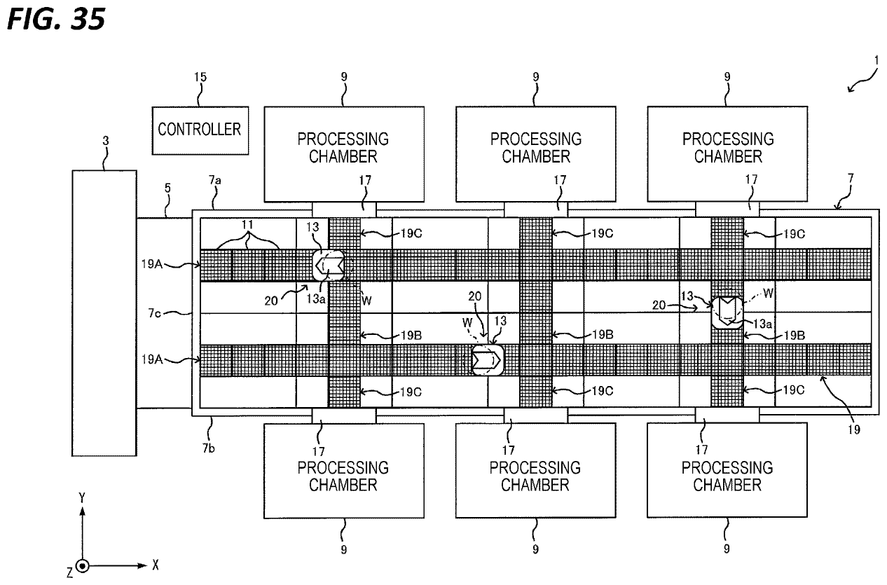

In the embodiment described above, the second transfer path 19B is formed at a position between two adjacent processing chambers 9 in the X-axis direction. However, as illustrated in FIG. 35, the second transfer path 19B may be formed at a position facing a processing chamber 9. In the present modification, the second transfer path 19B connects two first transfer paths 19A at a position facing the opening/closing door 17 of the processing chamber 9 in the Y-axis direction.

According to the present modification, for example, when the mover 13 moves between two processing chambers 9 facing each other in the Y-axis direction, the mover 13 may move along the shortest path.

### (8-2. Variation of Arrangement of Stators in Stator Unit)

In the embodiment described above, the upper surface of the base 32 of the stator unit 21 is divided into nine regions (3×3), and four stators 11 are arranged in a substantially T shape. However, the arrangement of the stators 11 is not limited thereto.

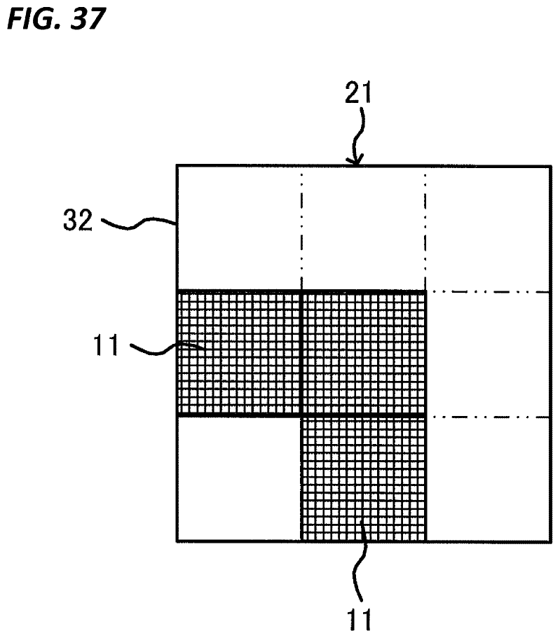

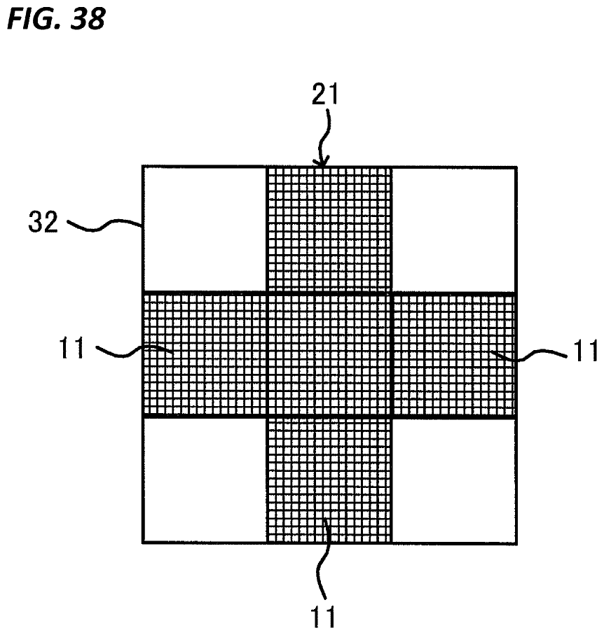

For example, as illustrated in FIG. 36, three stators 11 may be arranged in contact with the edges of two sides of the four sides of the base 32, to be arranged in a linear shape in the nine regions of the upper surface of the base 32. Further, as illustrated in FIG. 37, three stators 11 may be arranged in contact with the edges of two adjacent sides of the four sides of the base 32, to be arranged in a substantially L shape. Further, as illustrated in FIG. 38, for example, five stators 11 may be arranged in contact with the edges of all the four sides of the base 32, to be arranged in a substantially cross shape. By combining the various patterns of stator units 21 described above, the transfer path may be formed in various shapes.

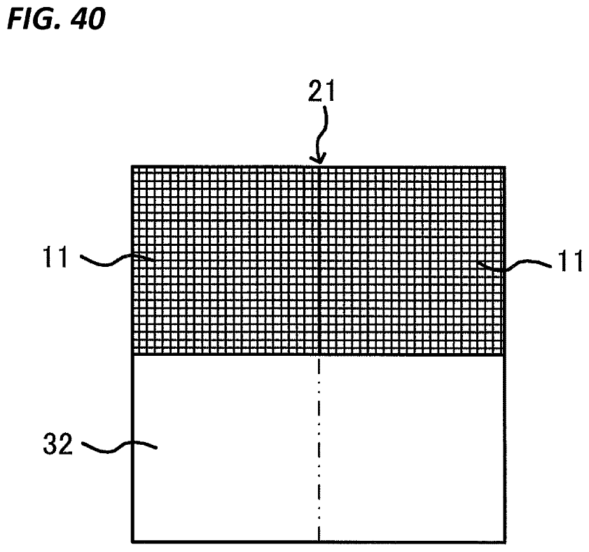

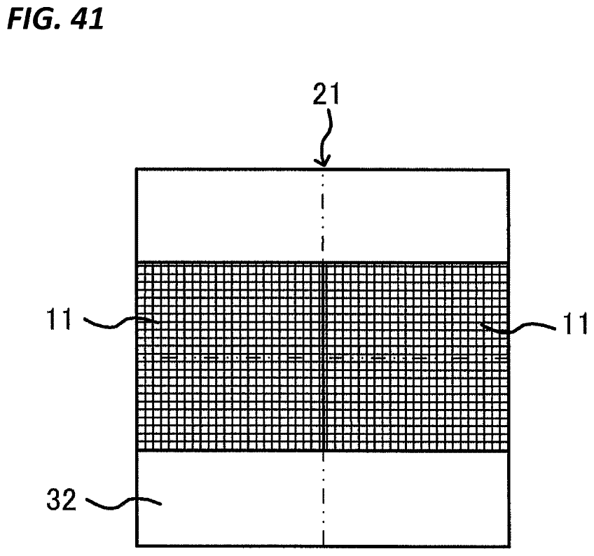

Further, as described in FIGS. 39 to 41, the upper surface of the base 32 may be divided into four regions (2×2) by being equally divided into two regions in both the longitudinal direction and the transverse direction, and the plurality of stators 11 may be arranged in predetermined regions of the four regions. For example, as illustrated in FIG. 39, three stators 11 may be arranged in contact with the edges of all the four sides of the base 32, to be arranged in a substantially T shape in the four regions of the upper surface of the base 32. For example, as illustrated in FIG. 40, two stators 11 may be arranged in contact with the edges of three sides of the four sides of the base 32, to be arranged in a linear shape in the four regions of the upper surface of the base 32. For example, as illustrated in FIG. 41, two stators 11 may be arranged in contact with the edges of two sides of the base 32 at the center portion of the base 32, to be arranged in a linear shape in the four regions of the upper surface of the base 32.

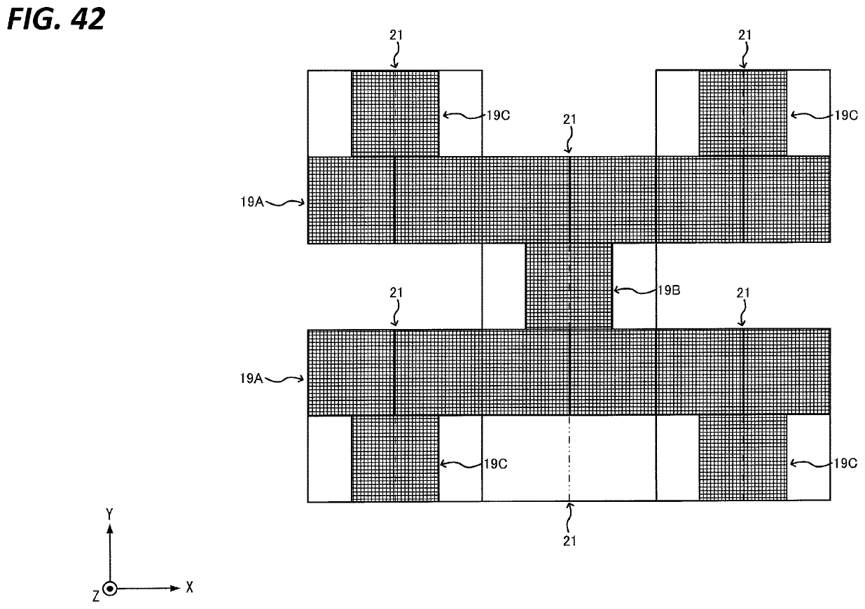

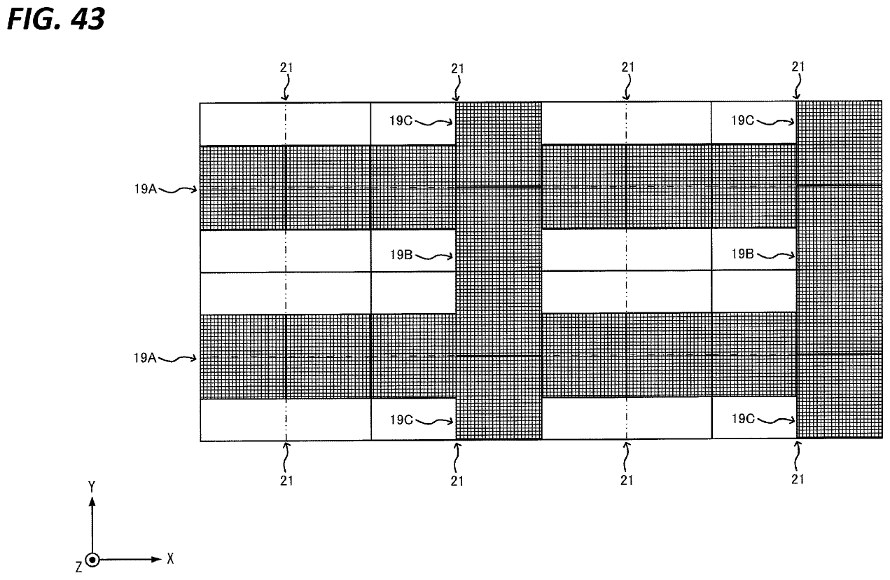

By connecting the stator units 21 of FIGS. 39 and 40 as illustrated in, for example, FIG. 42, the spacing between two spaced-apart first transfer paths 19A may be reduced from the spacing equivalent to two stators 11 to the spacing equivalent to one stator 11, as compared to the case where the upper surface of the base 32 is divided into nine regions (3×3). Therefore, the substrate transfer system 1 may be further downsized. Further, by connecting the stator units 21 of FIGS. 39 and 41 as illustrated in, for example, FIG. 43, the length of the third transfer path 19C in the Y-axis direction may be reduced to a half, as compared with the case of FIG. 42. Therefore, the substrate transfer system 1 may be further downsized.

### (8-3. When First Coil Patterns and Second Coil Patterns are Formed on Both Surfaces of Substrate)

In the embodiment described above, the first substrate with the first coil patterns formed thereon, and the second substrate with the second coil patterns formed thereon are provided as separate substrates. However, the first coil patterns and the second coil patterns may be formed on both surfaces of a common substrate.

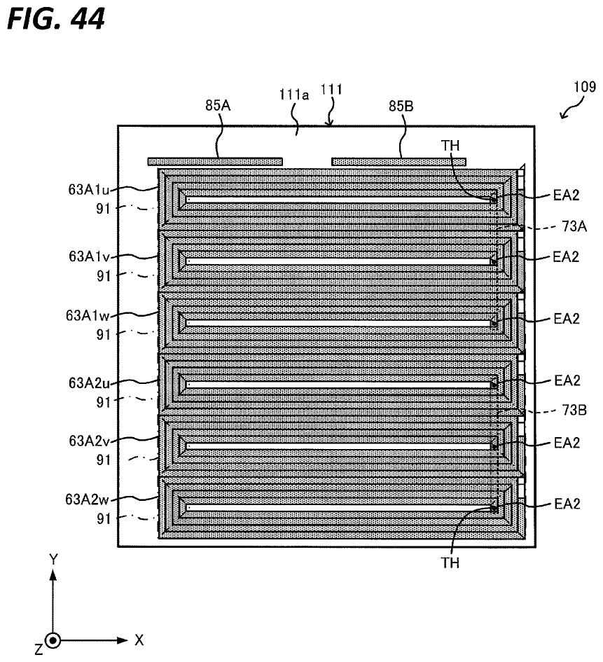

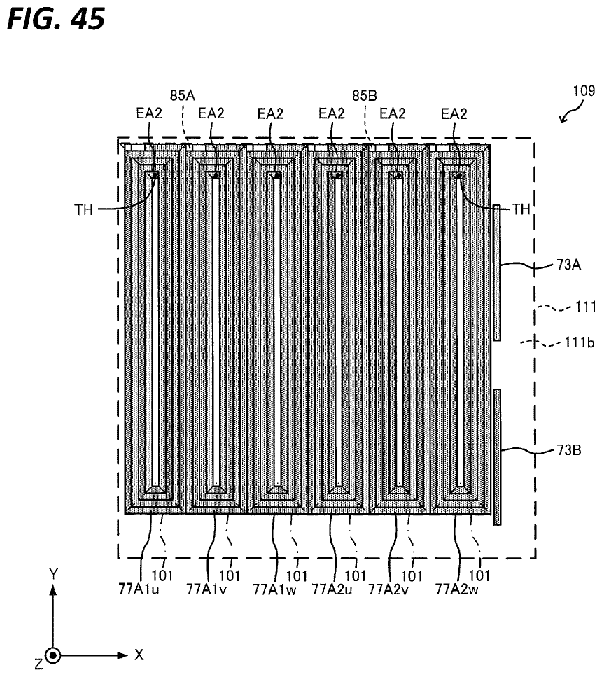

FIGS. 44 and 45 illustrate an example of the shape of the first coil patterns and the second coil patterns according to the present modification. FIG. 44 is a view of a substrate coil 109 when viewed from above in the Z-axis direction. As illustrated in FIG. 44, first coil patterns 63A1u, 63A1v, 63A1w, 63A2u, 63A2v, and 63A2w are formed on the front surface 111a of a substrate 111 (e.g., an example of a first surface). Since the configuration of the first coil patterns 63A1u, 63A1v, 63A1w, 63A2u, 63A2v, and 63A2w is the same as in FIG. 21 described above, detailed descriptions thereof are omitted. FIG. 45 is a view of the substrate coil 109 when viewed from above in the Z-axis direction through the substrate 111. As illustrated in FIG. 45, second coil patterns 77A1u, 77A1v, 77A1w, 77A2u, 77A2v, and 77A2w are formed on the rear surface 111b of the substrate 111 (e.g., an example of a second surface). Since the configuration of the second coil patterns 77A1u, 77A1v, 77A1w, 77A2u, 77A2v, and 77A2w is the same as in FIG. 24 described above, detailed descriptions thereof are omitted. The substrate coil 109 serves as both the first substrate coil and the second substrate coil.

As illustrated in FIG. 44, the end terminals EA2 of the first coil patterns 63A1u, 63A1v, and 63A1w are connected by the first neutral point 73A on the rear surface 111b of the substrate 111, via through holes TH, respectively. Similarly, the end terminals EA2 of the first coil patterns 63A2u, 63A2v, and 63A2w are connected by the first neutral point 73B on the rear surface 111b of the substrate 111, via through holes TH, respectively. As illustrated in FIG. 45, the first neutral points 73A and 73B are disposed apart from the second coil patterns 77A1u, 77A1v, 77A1w, 77A2u, 77A2v, and 77A2w.

As illustrated in FIG. 45, the end terminals EA2 of the second coil patterns 77A1u, 77A1v, and 77A1w are connected by the second neutral point 85A on the front surface 111a of the substrate 111, via through holes TH, respectively. Similarly, the end terminals EA2 of the second coil patterns 77A2u, 77A2v, and 77A2w are connected by the second neutral point 85B on the front surface 111a of the substrate 111, via through holes TH, respectively. As illustrated in FIG. 44, the second neutral points 85A and 85B are disposed apart from the first coil patterns 63A1u, 63A1v, 63A1w, 63A2u, 63A2v, and 63A2w. Further, a plurality of substrate coils 109 each configured as described above may be stacked in the Z-axis direction.

According to the present modification, the first coil patterns and the second coil patterns are formed on both surfaces of the substrate 111. As a result, as compared to the case where the first coil patterns and the second coil patterns are formed on separate substrates, the dimension in the stacking direction may be reduced (thinned).

### (8-4. Variation of Coil Configuration of Coil Unit)

In the embodiment described above, the coil unit 22 is configured such that the two sets of first substrate coils 23A and 23B, each including U-phase, V-phase, and W-phase substrate coils, and the two sets of the second substrate coils 25A and 25B, each including U-phase, V-phase, and W-phase substrate coils, are stacked in the Z-axis direction. However, the coil configuration of the coil unit 22 is not limited thereto.

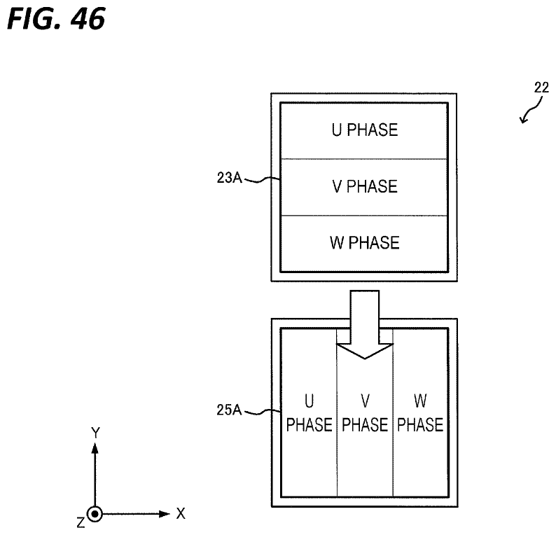

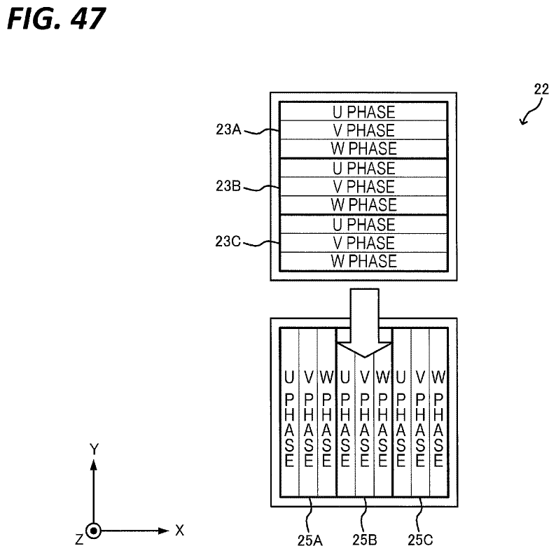

For example, as illustrated in FIG. 46, one set of first substrate coils 23A including U-phase, V-phase, and W-phase substrate coils, and one set of second substrate coils 25A including U-phase, V-phase, and W-phase substrate coils may be stacked in the Z-axis direction. Further, for example, as illustrated in FIG. 47, three or more sets of first substrate coils 23A, 23B, and 23C, each including U-phase, V-phase, and W-phase substrate coils, and three or more sets of second substrate coils 25A, 25B, and 25C, each including U-phase, V-phase, and W-phase substrate coils, may be stacked in the Z-axis direction.

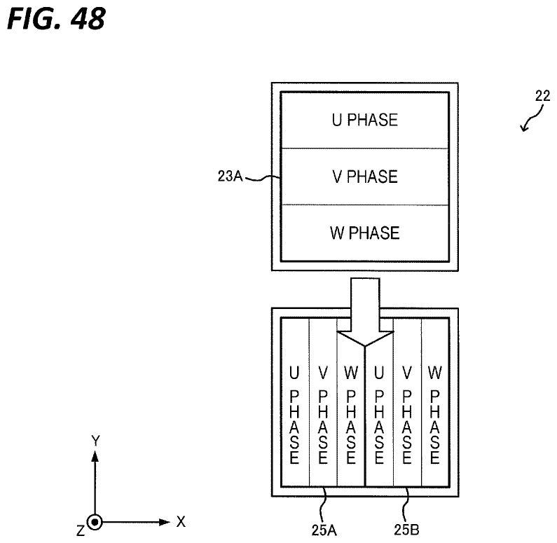

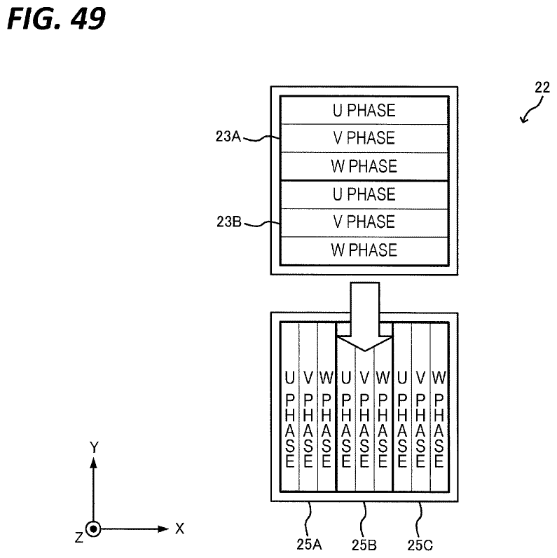

Further, when one set includes U-phase, V-phase, and W-phase substrate coils, the number of sets may differ between the first substrate coils and the second substrate coils. For example, as illustrated in FIG. 48, one set of first substrate coils 23A including U-phase, V-phase, and W-phase substrate coils, and two or more sets of second substrate coils 25A and 25B, each including U-phase, V-phase, and W-phase substrate coils, may be stacked in the Z-axis direction. Further, as illustrated in FIG. 49, two or more sets of first substrate coils 23A and 23B, each including U-phase, V-phase, and W-phase substrate coils, and three or more sets of second substrate coils 25A, 25B, and 25C, each including U-phase, V-phase, and W-phase substrate coils, may be stacked in the Z-axis direction.

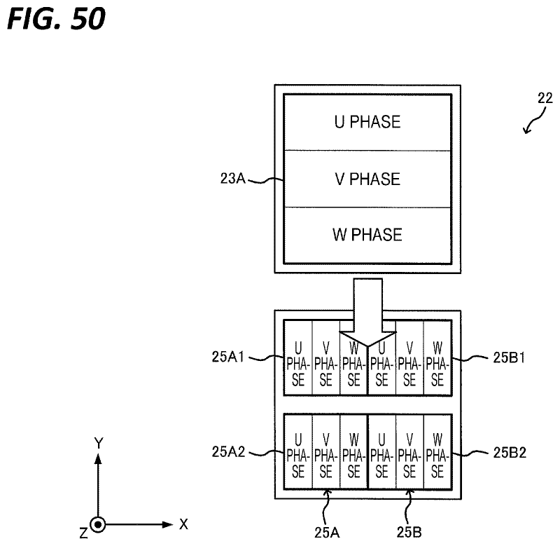

Further, either one or both the first substrate coils and the second substrate coils may be divided in the longitudinal direction. For example, as illustrated in FIG. 50, one set of first substrate coils 23A including U-phase, V-phase, and W-phase substrate coils, and two or more sets of second substrate coils 25A and 25B, each including U-phase, V-phase, and W-phase substrate coils, may be stacked in the Z-axis direction. In the second substrate coil 25A, two second substrate coils 25A1 and 25A2 are arranged separately in the longitudinal direction, and in the second substrate coil 25B, two second substrate coils 25B1 and 25B2 are arranged separately in the longitudinal direction.

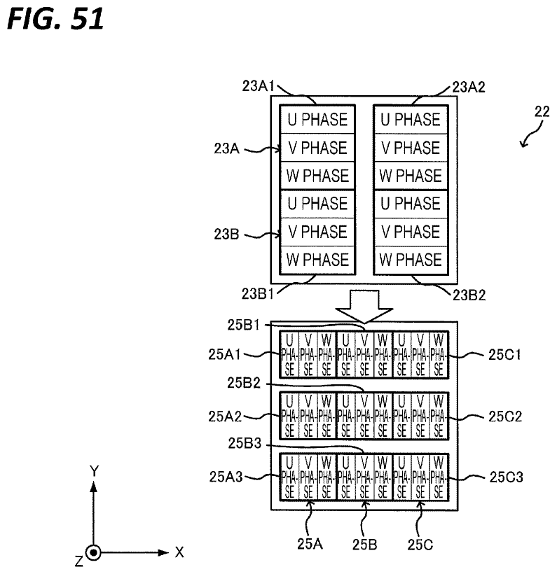

Further, as illustrated in FIG. 51, two or more sets of first substrate coils 23A and 23B, each including U-phase, V-phase, and W-phase substrate coils, and three or more sets of second substrate coils 25A, 25B, and 25C, each including U-phase, V-phase, and W-phase substrate coils, may be stacked in the Z-axis direction. In the first substrate coil 23A, two second substrate coils 23A1 and 23A2 are arranged separately in the longitudinal direction, and in the first substrate coil 23B, two first substrate coils 23B1 and 2 3B2 are arranged separately in the longitudinal direction. In the second substrate coil 25A, three second substrate coils 25A1, 25A2, and 25A3 are arranged separately in the longitudinal direction, in the second substrate coil 25B, three second substrate coils 25B1, 25B2, and 25B3 are arranged separately in the longitudinal direction, and in the second substrate coil 25C, three second substrate coils 25C1, 25C2, and 25C3 are arranged separately in the longitudinal direction.

### (8-5. Miscellaneous)

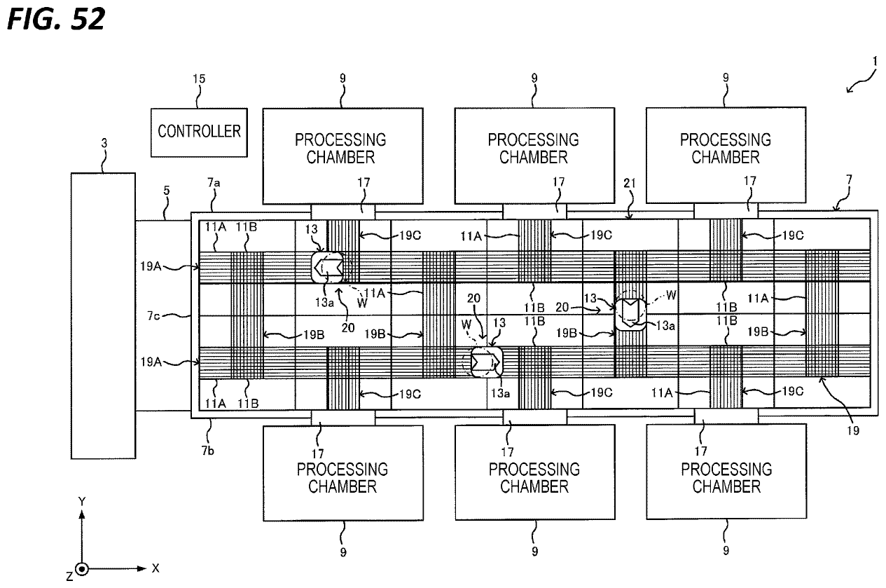

In the embodiment described above, all the stators 11 have the same coil configuration. However, the present disclosure is not limited thereto. For example, as illustrated in FIG. 52, when the stator 11 for moving the mover 13 in one linear direction is referred to as a first stator 11A (e.g., vertical hatching or horizontal hatching in FIG. 52), and the stator 11 for moving the mover 13 in two or more linear directions is referred to as a second stator 11B (e.g., grid hatching in FIG. 52), the winding configuration of substrate coils may differ between the substrate coils included in the first stator 11A and the substrate coils included in the second stator 11B. The winding configuration of substrate coils refers to, for example, wiring length of coil patterns making up the substrate coils, the number of turns, and the number of layers of a substrate. In general, the propulsion force required for the first stator 11A is smaller than the propulsion force required for the second stator 11B. Therefore, at least one of the wiring length of substrate coils, the number of turns, and the number of layers of a substrate for the second stator 11B may be made greater than that for the first stator 11A.

According to the present modification, the winding configuration of the substrate coils of the first stator 11A and the second stator 11B is set according to the propulsion force required for each stator, so that costs for the stators 11 may be reduced, as compared to a case where all the stators 11 have the same winding configuration.

In the foregoing descriptions, terms such as “vertical,” “parallel,” and “planar” do not indicate strict meanings. The terms “vertical,” “parallel,” and “planar” indicate “substantially vertical,” “substantially parallel,” and “substantially planar,” which allow design and manufacturing tolerances and errors.

In the foregoing description, when external dimensions, sizes, shapes, and positions, and the like, are “identical,” “the same,” “equal,” and “different,” etc., this description does not indicate a strict meaning. The terms “identical,” “the same,” “equal,” and “different” indicate “substantially identical,” “substantially the same,” “substantially equal,” and “substantially different,” which allow design and manufacturing tolerances and errors.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A transfer system comprising:
a transfer chamber equipped with a transfer path along which a workpiece is transferred;
a plurality of processing chambers arranged along a first direction around the transfer chamber, and configured to perform a predetermined process on the workpiece;
a plurality of stators each including a coil and arranged along the transfer path in the transfer chamber; and
a mover including a magnet and configured to levitate and move on the transfer path to transfer the workpiece,
wherein the transfer path includes a first transfer path in which the plurality of stators are arranged in a row along the first direction.

2. The transfer system according to claim 1, wherein the transfer path includes two first transfer paths that are spaced apart from each other in a second direction intersecting the first direction, and extend substantially parallel to the first direction.

3. The transfer system according to claim 2, wherein the transfer path includes at least one second transfer path that is formed by arranging at least one of the stators in a row along the second direction, and connects the two first transfer paths in the second direction.

4. The transfer system according to claim 3, wherein the second transfer path connects the two first transfer paths to each other at a position between two adjacent processing chambers in the first direction.

5. The transfer system according to claim 3, wherein the second transfer path connects the two first transfer paths to each other at a position facing an opening/closing door of a processing chamber in the second direction.

6. The transfer system according to claim 2, wherein the transfer path includes a third transfer path that is formed by arranging at least one of the stators in a row along the second direction, and connects the first transfer path and a processing chamber.

7. The transfer system according to claim 6, further comprising:
a stator unit configured as a unit including a base having a larger area than the stators when viewed from a third direction perpendicular to the first direction and the second direction, and the plurality of stators arranged on an upper surface of the base,
wherein the transfer path is formed by connecting a plurality of stator units.

8. The transfer system according to claim 7, wherein the stator unit is configured such that the plurality of stators are arranged adjacent to each other on the upper surface of the base.

9. The transfer system according to claim 8, wherein the stator unit is configured such that the base has a substantially quadrangular shape when viewed from the third direction, the upper surface of the base is divided into nine regions by being equally divided into three regions in both a longitudinal direction and a transverse direction, and the plurality of stators are arranged in predetermined regions of the nine regions.

10. The transfer system according to claim 9, wherein the stator unit is configured such that when viewed from the third direction, the stators are arranged in contact with edges of at least two sides of four sides of the base.

11. The transfer system according to claim 8, wherein the stator unit is configured such that the base has a substantially quadrangular shape when viewed from the third direction, the upper surface of the base is divided into four regions by being equally divided into two regions in both a longitudinal direction and a lateral direction, and the plurality of stators are arranged in predetermined regions of the four regions.

12. The transfer system according to claim 6, wherein when viewed from a third direction perpendicular to the first direction and the second direction, a dimension of the mover in at least one of the first direction and the second direction is substantially same as that of each stator.

13. The transfer system according to claim 12, wherein at least two movers are provided,
the transfer system further comprises a controller to individually control the movers, and
when the two movers move in a direction approaching each other on one of the two first transfer paths, the controller controls one of the two movers to move to a remaining first transfer path through the second transfer path such that the two movers pass each other.

14. The transfer system according to claim 12, wherein at least two movers are provided,
the transfer system further comprises a controller to individually control the movers, and
when the two movers move in a same direction on one of the two first transfer paths, the controller controls a mover on a rear side in a moving direction to move to a remaining first transfer path through the second transfer path, thereby overtaking a mover on a front side in the moving direction.

15. The transfer system according to claim 12, wherein at least two movers are provided,
the transfer system further comprises a controller to individually control the movers, and
when one mover of the two movers is present in front of a remaining mover that is moving on one of the two first transfer paths, the controller controls the remaining mover to move to a remaining first transfer path through the second transfer path, thereby bypassing the one mover.

16. The transfer system according to claim 12, wherein at least two movers are provided,
the transfer system further comprises a controller to individually control the movers, and
when each mover is moved toward a specific processing chamber connected to one first transfer path of the two first transfer paths, the controller controls the mover to move toward the specific processing chamber from one side in the first direction on the one first transfer path, or to detour from the one first transfer path through the second transfer path and a remaining first transfer path, thereby moving toward the specific processing chamber from an opposite side in the first direction.

17. The transfer system according to claim 12, wherein at least two movers are provided,
the transfer system further comprises a controller to individually control the movers, and
wherein the controller controls positions of the movers such that two or more movers are not located on a single stator.

18. The transfer system according to claim 12, wherein at least two movers are provided,
the transfer system further comprises a controller to individually control the movers, and a stator unit configured as a unit including a base having a larger area than the stators when viewed from the third direction perpendicular to the first direction and the second direction, and the plurality of stators arranged on an upper surface of the base, and
the controller controls positions of the movers such that two or more movers are not located on a single base.

19. The transfer system according to claim 12, wherein the plurality of stators include
a first stator configured to move the mover in one linear direction, and
a second stator configured to move the mover in two or more linear directions, and
the coil provided in the first stator and the coil provided in the second stator have different winding configurations.

20. The transfer system according to claim 7, wherein the stator unit includes
a nonmagnetic covering member that covers the plurality of stators disposed on the upper surface of the base, and
a heat transfer member disposed between the base and the stators to transfer heat generated in the stators to the base.
